(19) United States
(12) Patent Application Publication
(10) Pub. No.: US 2005/0000559 A1
(43) Pub. Date: Jan. 6, 2005

(54) Thermoelectric generator

(76) Inventors: Yuma Horio, Hamamatsu-shi (JP); Toshiharu Hoshi, Iwata-gun (JP); Takahisa Tachibana, Hamamatsu-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(21) Appl. No.: 10/805,523

(22) Filed: Mar. 22, 2004

(30) Foreign Application Priority Data
Mar. 24, 2003 (JP) 2003-080575
Mar. 26, 2003 (JP) 2003-086011
Dec. 17, 2003 (JP) 2003-419342

(51) Int. Cl. H01L 35/30

(52) U.S. Cl. 136/205

(57) ABSTRACT

A thermoelectric generator (e.g., a waste heat recovery apparatus) comprises a heat absorption member made of touch pitch copper and a thermoelectric module in which a plurality of thermoelectric elements are arranged to join electrodes between a pair of insulating substrates, thus utilizing waste heat emitted from a lamp having an exterior wall. One surface of the heat absorption member is formed to match the exterior wall of the lamp, and the other surface is formed to match the thermoelectric module, which is accompanied with a heat dissipating fin, which is further cooled by a cooling fan. At least a part of the heat absorption member can be arranged close to a light emitting tube of the lamp. The thermoelectric module generates electricity based on the heat transferred thereto from the lamp via the heat absorption member.

### BACKGROUND OF THE INVENTION

1. Field of the Invention

This invention relates to thermoelectric generators (e.g., waste heat recovery apparatuses) for generating electric power using waste heat emitted from electronic devices such as lamps so as to utilize the electric power for accommodating various devices such as projectors.

This application claims priority on Japanese Patent Application No. 2003-80575, Japanese Patent Application No. 2003-86011, Japanese Patent Application No. 2003-419342, and Japanese Patent Application (not assigned a number yet, claiming priority on Japanese Patent Application No. 2003-86011 in Japan), the contents of which are incorporated herein by reference.

2. Description of the Related Art

Conventionally, thermoelectric modules (e.g., thermoelectric converters) for performing thermoelectric conversion using the Peltier effect have been used for a variety of heating and cooling devices as well as electric power generators. A typical example of the thermoelectric module is constituted using a plurality of electrodes arranged at prescribed positions of a pair of insulating substrates facing each other, wherein the plurality of electrodes, which are arranged opposite to each other, are joined together with upper and lower ends of a plurality of thermoelectric elements by solders, so that the thermoelectric elements are fixedly arranged between the pair of the insulating substrates.

The aforementioned thermoelectric module is attached to one of two heat emitting components installed in an electronic device, wherein a cooling fan is activated using electricity generated in accordance with the temperature difference occurring between the insulating substrates, one of which is heated by one heat emitting component, so that the other heat emitting component installed in the electronic device is being cooled. An example of such a cooling device is disclosed in Japanese Patent No. 3107299.

In the above, if the heat emitting component which is installed in the electronic device and which is equipped with the thermoelectric module is designed to have a planar surface, it is possible to bring the overall surface of one insulating substrate of the thermoelectric module into contact with the heat emitting component of the electronic device, thus realizing efficient heat conduction. However, when the heat emitting component is constituted by a lamp and the like whose periphery has a curved exterior surface, only a part of the insulating substrate of the thermoelectric module can be brought into contact with the heat emitting component, thus deteriorating efficiency of heat recovery. In this case, it is difficult to sufficiently increase the temperature difference between the two insulating substrates. This reduces the electricity generated by the thermoelectric module very much.

In addition, thermoelectric modules can be attached to reflectors of lights of vehicles such as automobiles, whereby each of the thermoelectric module can generate electricity due to the temperature difference occurring between the insulating substrates, which are arranged opposite to each other and one of which is heated by the light, so that the electricity generated by the thermoelectric module can be reused for charging a vehicle's battery and the like. An example of such a battery charger is disclosed in Japanese Utility Model Application Publication No. Hei 6-49186.

When the aforementioned thermoelectric module is attached to the reflector of the vehicle's light, which is shaped to have a curved surface, only a part of the insulating substrate of the thermoelectric module can be brought into contact with the reflector; therefore, a heat recovery efficiency should be deteriorated. In addition, the vehicle's light is designed such that when it is turned on, a light emitting tube is increased in temperature while the exterior surface of the reflector incorporating a reflecting surface is maintained at a relatively low temperature. For this reason, the amount of heat being transferred from the reflector to the thermoelectric module becomes relatively small compared with the total amount of heat emitted by the light emitting tube. That is, it is difficult to increase the temperature difference between the insulating substrates of the thermoelectric module, which is thus reduced in the electric power generated therewith.

### SUMMARY OF THE INVENTION

It is an object of the invention to provide a thermoelectric generator (e.g., a waste heat recovery apparatus) that can efficiently utilize waste heat emitted or dissipated from a lamp and the like, thus generating relatively large amounts of electricity therewith.

A thermoelectric generator of this invention is characterized by providing a thermoelectric module comprising a pair of insulating substrates between which a plurality of thermoelectric elements are arranged and brought into contact with upper and lower electrodes, wherein the thermoelectric module is attached to the exterior peripheral surface of a lamp, by which one insulating substrate is heated so as to increase the temperature difference between the pair of the insulating substrates so that the thermoelectric module generates electricity. Herein, this invention is characterized by arranging a heat absorption member between one insulating substrate of the thermoelectric module and the exterior peripheral surface of the lamp.

Due to the provision of the heat absorption member, it is possible to actualize an efficient heat conduction (or an efficient heat transfer) between one insulating substrate of the thermoelectric module and the exterior peripheral surface of the lamp, which are arranged close to each other. This contributes to an increase of the temperature difference between the insulating substrates that are arranged oppositely in proximity to each other in the thermoelectric module, which is thus increased in the electric power generated therewith.

In the above, the heat absorption member is adequately shaped in such a way that one surface thereof is shaped to match the exterior peripheral surface of the lamp, while the other surface thereof is shaped to match the surface of the thermoelectric module. Due to such shaping of the heat absorption member, it is possible to improve the heat conductivity between the lamp and the thermoelectric module, which is thus increased in the electric power generated therewith. The other insulating substrate of the thermoelectric module, which is opposite to the insulating surface directly facing the heat absorption member, is cooled by a cooling fan and the like; thus, it is possible to further increase the temperature difference between the pair of the insulating substrates in the thermoelectric module, which is thus further increased in the electric power generated therewith. Incidentally, it is preferable to use prescribed materials, which provide a great heat conductivity and processability, for use in the formation of the heat absorption member.

One insulating substrate of the thermoelectric module can be constituted using a thin film, by which it is possible to improve a heat conductivity between the heat absorption member and the thermoelectric module, which is thus further increased in the electric power generated therewith. In this case, it is preferable to integrally form both of the heat absorption member and the thermoelectric module together.

The aforementioned heat absorption member can be made of a prescribed material such as copper and aluminum, each of which provide a relatively high thermal conductivity. Due to such a relatively high thermal conductivity, the heat absorption member can efficiently absorb the heat emitted from the lamp. Thus, it is possible to actualize an efficient heat conduction between the lamp and the heat absorption member and between the heat absorption member and the thermoelectric module. By using aluminum as the material for the formation of the heat absorption member, it is possible to reduce the overall weight of the thermoelectric generator.

In addition, this invention is characterized by arranging a thermal resistance reducing layer, made of grease, carbon, or resin each having a relatively high heat resistance and a relatively high heat conductivity in the gap (or boundary) between the heat absorption member and the exterior peripheral surface of the lamp. This noticeably reduces the thermal resistance between the heat absorption member and the exterior peripheral surface of the lamp; thus, it is possible to realize further efficient heat conduction between the lamp and the heat absorption member.

In the above, prescribed portions of the heat absorption member except its exterior surfaces facing with the lamp and the thermoelectric module are coated with heat insulating materials, by which it is possible to noticeably reduce the amount of heat that is dissipated to the exterior without being transmitted from the heat absorption member to the thermoelectric module; thus, it is possible to actualize an effective heat conduction between the heat absorption member and the thermoelectric module. That is, it is possible to realize an effective recovery of the heat emitted from the lamp without being wasted so much.

A typical example of an apparatus using the aforementioned thermoelectric generator is a projector in which a lamp emits heat that is converted into electricity, which is recovered for use in the light emission of the lamp or for use in operations of other components installed in the projector.

The projector comprises a display for display images on the screen and a Peltier element, wherein the Peltier element is supplied with the electricity generated by the thermoelectric element so as to adjust the temperature of the display. That is, the electricity that the thermoelectric module generates upon recovery of the waste heat emitted from the lamp can be reused for activating the Peltier element, by which the temperature of the display is being adjusted, whereby it is unnecessary to provide an extra power source for activating the temperature adjustment for the display, which can be therefore constituted by a certain device in which a plurality of small metal mirrors are arranged on a silicone substrate in order to control the reflecting direction of the incoming light. This device is effective for the temperature adjustment because it can be easily heated by a light source (e.g., a lamp).

The aforementioned thermoelectric module is arranged above the lamp in order to effectively transmit the heat, which is emitted from the lamp and moves upwardly, towards the thermoelectric module, which thus realizes an efficient electric power generation. Herein, it is preferable to arranged the lamp to be directed downwardly in light emission direction, whereby the exterior peripheral surface of the lamp can be totally directed upwards so that the heat emitted from the lamp can be efficiently transmitted to the thermoelectric module.

The aforementioned projector is advantageous in that no cooling fan is specifically required for cooling the lamp. In the conventional projector, a pair of fans are arranged on the right and the left of the lamp, wherein one fan blows out to cause air flow towards the lamp, and the other fan blows in to release the air from the lamp, that is, these fans cause the air flow from one side to the other side of the lamp, which is thus cooled.

In contrast to the conventional projector, the projector of this invention is characterized by providing the heat absorption member, which absorbs the heat, which is emitted from the lamp and moves upwards; thus, no cooling fan is specifically required for the projector. As a result, this invention can noticeably reduce the total consumption of electricity in the projector, which can be thus reduced in size.

When the lamp is directed horizontally in light emission direction, the heat absorption member and thermoelectric module are arranged above the lamp, while the heat insulating materials are arranged under the lamp.

Incidentally, each of the thermoelectric elements installed in the thermoelectric module can be preferably made of a prescribed material, which is a combination between at least one of bismuth and antimony and at least one of tellurium and selenium, whereby it is possible to allow the thermoelectric element to increase the temperature difference between both ends thereof; and it is possible to noticeably increase the amount of the electric power generated by the thermoelectric module.

A thermoelectric generator of this invention comprises a thermoelectric module having thermoelectric elements whose ends join electrodes formed on interior surfaces of first and second insulating substrates that are arranged opposite to each other, wherein the thermoelectric module is attached to a lamp comprising a light emitting tube and an exterior wall, which protects and supports the light emitting tube, thus generating electric power due to the temperature difference occurring between the first insulating substrate, which is heated by the heat caused by the light emitting tube, and the second insulating substrate. Herein, a heat absorption member is arranged between the first insulating substrate and the light emitting tube, and a part of the heat absorption member is arranged inside of the lamp.

That is, the heat absorption member that is partially inserted into the lamp can absorb and transfer the high-temperature heat caused by the lamp to the thermoelectric module, which is activated to generate a relatively great amount of electric power. Herein, a part of the exterior wall of the lamp can be constituted using the heat absorption member, which is thus substantially installed inside of the lamp.

In the above, the thermoelectric module is attached to the backend portion of the lamp, and the heat absorption member is arranged between the first insulating substrate and the backend portion of the lamp, wherein a part of the heat absorption member is arranged inside of the lamp. Thus, it is possible for the heat absorption member to absorb the heat emitted from the exterior peripheral surface of the exterior wall of the lamp in proximity to its backend portion, wherein the heat absorption member also absorbs the high-temperature heat directly emitted from the light emitting tube inside of the lamp.

As a result, it is possible to efficiently perform heat conduction from the lamp to the first insulating substrate of the thermoelectric module, whereby it is possible to noticeably increase the temperature difference between the first insulating substrate and second insulating substrate of the thermoelectric module, which is thus increased in the electric power generated therewith. Herein, it is preferable to cool the second insulating substrate by means of a cooling fan, thus further increasing the temperature difference between the first and second insulating substrates of the thermoelectric module.

It is possible to modify the aforementioned thermoelectric generator such that a part of the heat absorption member is elongated to penetrate through the exterior wall of the lamp from its exterior peripheral surface to its interior peripheral surface, and the tip end portion of the heat absorption member is broadened along the interior peripheral surface of the exterior wall of the lamp. That is, a prescribed part (e.g. a projecting portion) of the heat absorption member can be elongated close to the light source of the light emitting tube and is broadened over a relatively large area along the interior peripheral surface of the exterior wall of the lamp. Thus, it is possible to actualize an efficient heat conduction in which the heat caused by the light emitting tube is efficiently transferred to the heat absorption member, so that the thermoelectric module can be further increased in the electric power generated therewith. In the above, a part of the heat absorption member, which is broadened along the interior peripheral surface of the exterior wall of the lamp, can be formed like a dome or a radial pattern.

It is possible to further modify the thermoelectric generator such that a part of the heat absorption member is extended inside of the internal space of the exterior wall of the lamp encompassing the light emitting tube. That is, it is possible to arrange a part of the heat absorption member in a relatively large area and close to the light source of the light emitting tube without unnecessarily narrowing the total area of a reflection surface that is formed on the interior peripheral surface of the exterior wall of the lamp. Thus, it is possible to efficiently transfer the heat caused by the light emitting tube towards the heat absorption member, so that the thermoelectric module is increased in the electric power generated therewith without causing unwanted influences to the illumination effect of the lamp.

A part of the heat absorption member can be arranged along a boundary between the light emitting tube and the exterior wall supporting the light emitting tube, wherein it is formed in the surrounding area of the light emitting tube, thus realizing an efficient heat conduction from the light emitting tube to the heat absorption member. This actualizes a simple structure for the heat absorption member, which can be thus manufactured with ease.

In the above, a part of the heat absorption member can be arranged to penetrate through the exterior wall of the lamp from its exterior peripheral surface to its interior peripheral surface, wherein it is elongated close to the light source inside of the high-temperature internal space of the lamp encompassed by the exterior wall; hence, it is possible to actualize an effective heat conduction towards the heat absorption member.

The aforementioned light emitting tube can be modified such that an internal space is formed lying from the backend thereof to the light source thereof, wherein a part of the heat absorption member is elongated inside of the internal space of the light emitting tube. That is, a part of the heat absorption member enters into the very high temperature internal space of the light emitting tube; hence, it is possible to transfer a very great amount of heat from the light emitting tube to the heat absorption member.

A part of the exterior wall of the lamp can be constituted using the heat absorption member, which can be arranged at any position of the exterior wall and which can be adequately designed in shape and size to suit the thermoelectric module. For example, a relatively large area of the exterior wall of the lamp can be formed using the heat absorption member, which therefore effectively absorb the heat emitted from the light emitting tube so as to increase the electric power generated by the thermoelectric module.

In addition, the heat absorption member can be designed hollow providing an internal space therein, which communicated with the internal space of the lamp encompassed by the exterior wall. Thus, it is possible to increase the total area of the heat absorption member for absorbing the heat emitted from the lamp. Herein, it is possible to additionally form a plurality of fins on the interior surface of the internal space of the heat absorption member, whereby it is possible to further increase the heat absorbing area of the heat absorption member; hence, it is possible to further increase the electric power generated by the thermoelectric module. Incidentally, it is possible for the heat absorption member to form heat dissipating holes communicating with the exterior thereof, by which it is possible to prevent the temperature of the lamp from being increased so much; hence, it is possible to increase the lifetime of the lamp.

The exterior peripheral surface of the exterior wall of the lamp can be covered with a heat insulating material except the prescribed area accompanied with the heat absorption member. Due to the provision of the heat insulating material, it becomes almost possible to prevent the waste heat from being released from the exterior peripheral surface of the exterior wall of the lamp except at the prescribed area accompanied with the heat absorption member. Thus, it is possible for the heat absorption member to efficiently absorb and transfer the heat emitted from the lamp towards the thermoelectric module, which is thus improved in an electricity generation efficiency.

The aforementioned thermoelectric generator can be installed in a projector including a lamp, wherein it converts the heat of the lamp into electricity, which is reused for the lamp to emit light or which is used to operate other components arranged in the projector.

For example, a Peltier element is arranged to adjust the temperature of a display that is arranged in the projector to project an image on the screen, wherein the electric power generated by the thermoelectric module is supplied to the Peltier element, which is activated to adjust the temperature of the display. In addition, the electric power generated by the thermoelectric module can be used to operate cooling fans installed in the projector. Furthermore, the electric power generated by the thermoelectric module can be used to operate other components of the projector and/or other external devices. Herein, this invention is advantageous in that substantially no extra power source may be necessary to operate various devices because the waste heat emitted from the lamp and the like can be efficiently recovered and used to generate electric power by means of the thermoelectric module.

### BRIEF DESCRIPTION OF THE DRAWINGS

These and other objects, aspects, and embodiments of the present invention will be described in more detail with reference to the following drawings, in which:

FIG. 1 is a schematic illustration showing the constitution of a projector in accordance with a first embodiment of the invention;

FIG. 2 is a schematic illustration showing components and connections of a lamp unit installed in the projector shown in FIG. 1;

FIG. 3 is a front view showing essential parts of the lamp unit;

FIG. 4 is a side view showing essential parts of the lamp unit;

FIG. 5 is a perspective view showing the constitution of a thermoelectric module incorporated in the lamp unit;

FIG. 6 is a front view showing essential parts of the thermoelectric module;

FIG. 7 is a front view showing essential parts of a lamp unit arranged in a projector in accordance with a second embodiment of the invention;

FIG. 8 is a front view showing essential parts of a lamp unit arranged in a projector in accordance with a third embodiment of the invention;

FIG. 9 is a side view showing essential parts of the lamp unit shown in FIG. 8;

FIG. 10 is a front view showing essential parts of a projector in accordance with a fifth embodiment of the invention;

FIG. 11 is a front view showing essential parts of a lamp unit, which is created as Example 8 for testing;

FIG. 12 is a front view showing essential parts of a lamp unit, which is created as Example 9 for testing;

FIG. 13 is a front view showing essential parts of a lamp unit, which is created as Example 10 for testing;

FIG. 14 is a schematic illustration showing the constitution of a projector in accordance with a sixth embodiment of the invention;

FIG. 15A is a plan view diagrammatically showing the constitution of a projector having a thermoelectric generator in accordance with a seventh embodiment of the invention;

FIG. 15B is a side view diagrammatically showing the projector shown in FIG. 15A;

FIG. 16 is a schematic illustration showing the constitution of the thermoelectric generator shown in FIGS. 15A and 15B;

FIG. 17 is a schematic illustration showing the constitution of a thermoelectric generator that is modified compared with the thermoelectric generator shown in FIG. 16;

FIG. 18 is a schematic illustration showing the constitution of a thermoelectric generator that is further modified;

FIG. 19 is a schematic illustration showing the constitution of a thermoelectric generator that is further modified;

FIG. 20 is a schematic illustration showing the constitution of a thermoelectric generator that is further modified;

FIG. 21 is a schematic illustration showing the constitution of a thermoelectric generator, which is designed as a comparative example used in testing;

FIG. 22 is a schematic illustration showing the constitution of a thermoelectric generator that is further modified;

FIG. 23 is a schematic illustration showing the constitution of a thermoelectric generator that is further modified;

FIG. 24 is a schematic illustration showing the constitution of a thermoelectric generator that is further modified;

FIG. 25 is a front view of the thermoelectric generator shown in FIG. 24;

FIG. 26 is a front view of a thermoelectric generator, which is further modified compared with the thermoelectric generator shown in FIG. 25;

FIG. 27 is a schematic illustration showing the constitution of a thermoelectric generator that is further modified;

FIG. 28 is a schematic illustration showing the constitution of a thermoelectric generator, which is further modified compared with the thermoelectric generator shown in FIG. 27;

FIG. 29 is a schematic illustration showing the constitution of a thermoelectric generator, which is further modified compared with the thermoelectric generator shown in FIG. 28;

FIG. 30 is a table showing results of testing on Example 1 to Example 7 in comparison with a comparative example;

FIG. 31 is a table showing results of testing on Example 8 to Example 10, which are respectively shown in FIGS. 11 to 13; and

FIG. 32 is a side view diagrammatically showing a further modified example of a projector.

### DESCRIPTION OF THE PREFERRED EMBODIMENTS

This invention will be described in further detail by way of examples with reference to the accompanying drawings.

1. First Embodiment

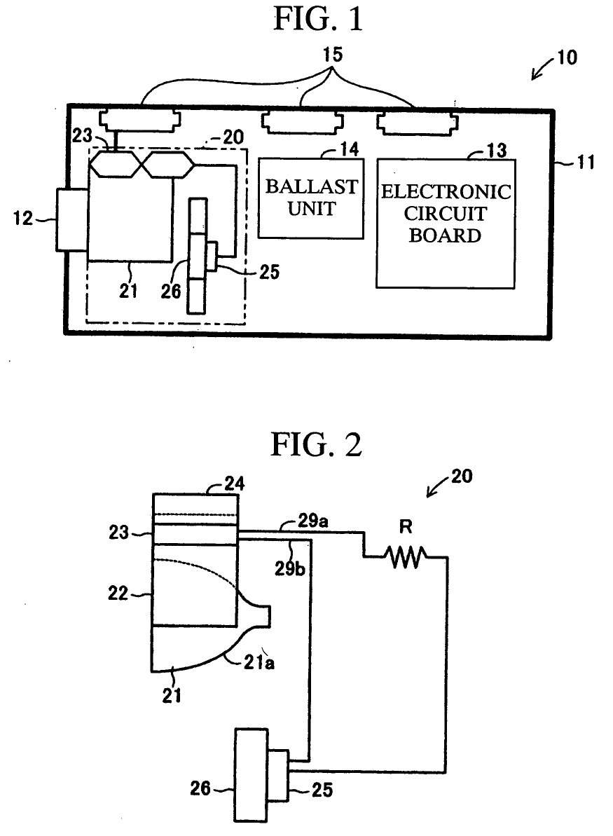

FIG. 1 shows a projector 10 actualizing a thermoelectric generator in accordance with a first embodiment of the invention. The projector 10 comprises a lamp unit 20, a lens 12, an electronic circuit board 13, a ballast unit 14, and cooling fans 15, all of which are incorporated in a housing 11 having a box-like shape.

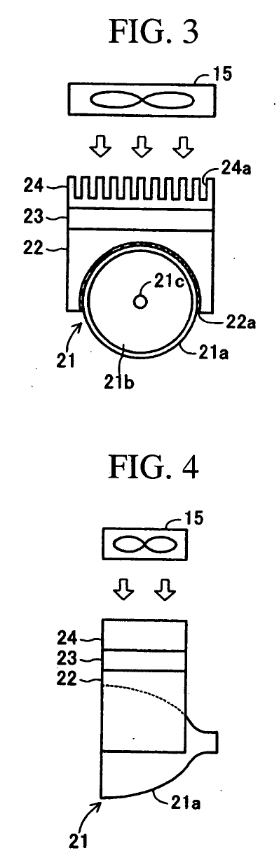

As shown in FIG. 2, the lamp unit 20 comprises a lamp 21, a heat absorption member 22, a thermoelectric module (or a thermoelectric converter) 23, a heat dissipating fin 24, a Peltier element 25 for cooling, and a display 26 constituted by a certain device in which a plurality of metal mirrors are arranged on a silicone substrate. The exterior peripheral surface of the lamp 21 having an exterior wall 21a serves as a reflector, wherein as shown in FIGS. 3 and 4, it is formed like a dome-shaped ceramic body, the front side of which is formed as a circular opening, the peripheral side of which is gradually reduced in dimensions towards the backend thereof, and the backend of which is closed.

A transparent glass 21b is attached to the opening formed in the front side of the exterior wall 21a of the lamp 21, wherein a light source 21c is arranged at the center of the backend portion of the exterior wall 21a inside of the lamp 21. The light source 21c is constituted by an extra-high pressure mercury lamp, wherein when turned on, the internal pressure thereof may reach 200 units of atmospheric pressure, and the temperature thereof may reach 1000° C., for example. In this case, the temperature of the exterior wall 21a of the lamp 21 is increased up to 220° C. or so.

A heat absorption member 22 is constituted as a block made of a touch pitch copper, wherein the upper surface thereof is formed planar, and the lower surface thereof is curved to follow the curved exterior wall 21a of the lamp 21. A heat transfer grease layer 22a is arranged as a thermal resistance reducing layer in the boundary between the exterior wall 21a of the lamp 21 and the heat absorption member 22. The heat transfer grease layer 22a is made of a silicone having high heat resistance and high heat conduction, which contributes to improvement of the heat conduction with respect to the transfer of heat from the lamp 21 to the heat absorption member 22. The touch pitch copper forming the heat absorption member 22 has a heat conductivity of 0.93. Thus, the heat absorption member 22 can transfer most of the heat, which is emitted from the lamp 21 and is efficiently transmitted via the heat transfer grease layer 22a, towards the thermoelectric module 23.

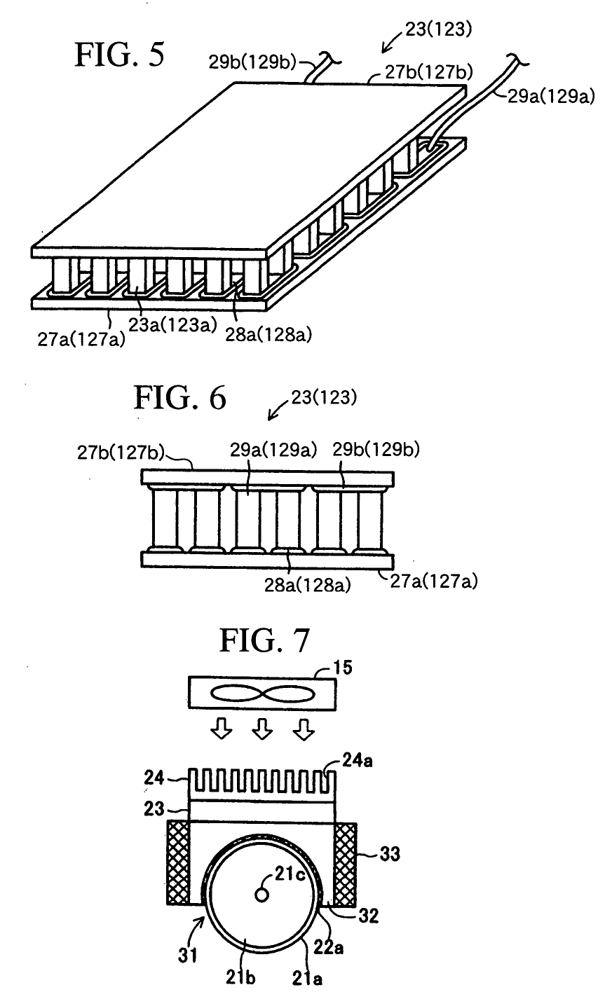

As shown in FIGS. 5 and 6, the thermoelectric module 23 comprises a pair of insulating substrates, namely, a lower substrate 27a and an upper substrate 27b, wherein plural lower electrodes 28a are attached to prescribed positions on the upper surface of the lower substrate 27a, and a plurality of upper electrodes 28b are attached to prescribed positions on the lower surface of the upper substrate 27b. A plurality of thermoelectric elements 23a constituted by chips are fixedly arranged between the lower substrate 27a and the upper substrate 27b in such a way that the lower ends thereof join the lower electrodes 28a by solder, and the upper ends thereof join the upper electrodes 28b by solder. Thus, the lower substrate 27a and the upper substrate 27b are integrally interconnected together by the thermoelectric elements 23a.

In the above, the lower substrate 27a and the upper substrate 27b are separated from each other with a prescribed distance therebetween, which substantially matches a single thermoelectric module 23a. Specifically, the upper ends of two thermoelectric elements 23a join each single upper electrode 28b of the upper substrate 27b, while the lower substrate 27a provides two types of lower electrodes 28a, that is, the lower end of a single thermoelectric element 23a joins each single lower electrode 28a of the first type, and the lower ends of two thermoelectric elements 23a join each single lower electrode 28a of the second type. Herein, the lower electrodes 28a of the first type in which each single lower electrode joins the lower end of a single thermoelectric module are respectively arranged at two corners of the lower substrate 27a along its one side (see FIG. 5), wherein they are respectively connected with leads 29a and 29b allowing electric transmission towards an external device (not shown).

Each of the lower substrate 27a and the upper substrate 27b is constituted by an alumina plate. Each of the thermoelectric elements 23a is formed in a rectangular parallelopiped shape made of a bismuth-tellurium alloy in correspondence with a p-type element or a n-type element. The thermoelectric elements 23a are connected in series via the lower electrodes 28a and the upper electrodes 28b between the lower substrate 27a and the upper substrate 27b. Hence, the thermoelectric module 23 having the aforementioned constitution is fixed to the upper surface of the heat absorption member 22, via which a part of the heat caused by the light emission of the lamp 21 is transferred thereto. Thus, the thermoelectric module 23 generates electricity due to the temperature difference occurring between the lower substrate 27a, which is heated by the heat emitted from the lamp 21, and the upper substrate 27b, which is not heated. The aforementioned projector 10 (see FIG. 1) is equipped with the two thermoelectric modules 23.

The heat dissipating fin 24 is formed as a block made of aluminum, wherein a plurality of heat dissipating grooves 24a are arranged with prescribed distances therebetween on the upper surface and are formed to pass through in front-back directions thereon. The heat dissipating fin 24 is fixed to the upper surface of the upper substrate 27b of the thermoelectric module 23. Due to the formation of the plurality of heat dissipating grooves 24a, the overall upper area of the heat dissipating fin 24 is increased so as to improve a heat radiation ability, whereby it increases the amount of heat emitted from the upper substrate 27b of the thermoelectric module 23. Thus, it is possible to increase the temperature difference between the lower substrate 27a and the upper substrate 27b of the thermoelectric module 23, which is thus increased in electricity generated therefrom.

Ends of the leads 29a and 29b extended from the thermoelectric module 23 are connected to the Peltier element 25 for use in cooling. The Peltier element 25 is constituted similar to the thermoelectric module 23; hence, it can convert electricity supplied thereto from the thermoelectric module 23 via the leads 29a and 29b into heat. In the present embodiment, the Peltier element 25 is used for the purpose of cooling the display 26.

The display 26 is constituted by aligning a plurality of metal mirrors on the silicon substrate, wherein the incoming light is subjected to reflection while controlling the reflecting direction therefor, so that an image is projected onto a screen (not shown) via the lens 12. The display 26 cannot operate normally and will be reduced in lifetime when the temperature thereof becomes high. For this reason, the display 26 should be cooled by the Peltier element 25.

A conduction circuit is printed on the electronic circuit board 13 installed in the housing 11, whereby various components and circuits of the projector 10 are electrically connected together via the conduction circuit. The ballast unit 14 comprises a stabilizer by which constant electric power is normally supplied to the lamp 21, regardless of fluctuations of the electric power applied to the projector 10. Thus, the lamp 21 can emit light in a stable manner. A plurality of cooling fans 15 are arranged in a plurality of openings (not shown specifically in FIG. 1), which are formed at prescribed positions of the housing 11, whereby external air is introduced into the housing 11 so as to cool various components and devices installed in the housing 11. A part of the cooling fans 15 is connected with the thermoelectric module 23 so as to operate based on the electricity generated by the thermoelectric module 23.

Other than the aforementioned components and circuits, the projector 10 of the present embodiment further comprises a power source for supplying electric power to the components and circuits arranged therein, various switches and operation buttons, and input/output terminals for inputting video data and audio data and for outputting various data and signals in connection with an external device such as a personal computer.

In order to operate the projector 10 having the aforementioned constitution, a plug or a connector of a wiring cord of an external device (e.g., a personal computer) is connected with the input/output terminals so as to allow transmission and reception of data between the projector 10 and the external device; then, the user (or human operator) turns on a power switch (not shown) and operates the operation button(s). Thus, the lamp 21 is turned on to emit light; and the display 26 and various components of the projector 10 starts to operate, so that a prescribed image is projected on the screen by means of the lens 12.

While the projector 10 is operating, the inside temperature of the housing 11 increases due to the heat caused by the light emission of the lamp 21 and the heat emitted from the display 26 and other components. In this case, the cooling fans 15 are activated so as to make air flow inside of the housing 11, which is thus cooled down. Herein, the heat emitted from the prescribed surface of the lamp 21 facing the heat absorption member 22 is transferred via the heat transfer grease layer 22a and is absorbed in the heat absorption member 22: then, the heat is transmitted to the lower substrate 27a of the thermoelectric module 23.

In the above, the lower surface of the heat absorption member 22 is adequately curved to match the ‘curved’ exterior wall 21a of the lamp 21, and the heat transfer grease layer 22a is arranged in the gap between the exterior wall 21a and the heat absorption member 22; hence, it is possible to perform heat transfer (or heat conduction) efficiently. The upper substrate 27b of the thermoelectric module 23 is cooled by the heat dissipating function of the heat dissipating fin 24 and is also subjected to air cooling due to the air flow caused by the cooling fans 15.

As a result, a relatively large temperature difference occurs between the lower ends of the thermoelectric elements 23a, in proximity to the lower substrate 27a, and the upper ends of the thermoelectric elements 23a, in proximity to the upper substrate 27b; thus, the thermoelectric module 23 generates electricity due to the temperature difference therein. A part of the electric power generated by the thermoelectric module 23 is supplied to the Peltier element 25, and the other part is supplied to the cooling fans 15; thus, both of the Peltier element 25 and the cooling fans 15 operate based on the electric power generated by the thermoelectric module 23.

The Peltier element 25 is constituted similar to the thermoelectric module 23; therefore, it will be described with reference to FIG. 5 showing the constitution of the thermoelectric module 23. The electric power generated by the thermoelectric module 23 is supplied via the leads 29a and 29b to the Peltier element 25, which is connected with the thermoelectric module 23 in such a way that heat absorption occurs in the upper substrate of the Peltier element 25, and the heat dissipation occurs in the lower substrate of the Peltier element 25, in other words, a prescribed voltage is applied to the Peltier element 25 such that carriers move from the upper substrate to the lower substrate (see FIG. 5 in which carriers may move from the upper substrate 27b to the lower substrate 27a via the thermoelectric element 23a). Therefore, the Peltier element 25 is arranged such that the upper substrate thereof is brought into contact with the display 26, which is thus cooled. Thus, it is possible to maintain the display 26 at the appropriate temperature; hence, it is possible to produce a good picture quality and to realize a relatively long lifetime with respect to the display 26. Incidentally, the vertical direction for arranging the thermoelectric module 23 should be adequately changed in response to the arrangement of p-type elements and n-type elements thereof.

As described above, the projector 10 of the present embodiment is characterized by providing the heat absorption member 22 having a superior heat conductivity between the thermoelectric module 23 and the exterior wall 21a of the lamp 21, wherein the lower surface of the heat absorption member 22 is appropriately shaped to match the ‘curved’ exterior wall 21a of the lamp 21, while the upper surface of the heat absorption member 22 is made planar. This allows the lower surface of the heat absorption member 22 to come in contact with the exterior wall 21a of the lamp 21 in a relatively large area; and this also allows the upper surface of the heat absorption member 22 to be in tight contact with the lower substrate 27a of the thermoelectric module 23.

Due to the provision of the heat transfer grease layer 22a between the exterior wall 21a of the lamp 21 and the lower surface of the heat absorption member 22, it is possible to actualize an efficient heat conduction (or heat transfer) from the lamp 21 to the heat absorption member 22 and to actualize an efficient heat conduction (or heat transfer) from the heat absorption member 22 to the lower substrate 27a of the thermoelectric module 23. In addition, the upper substrate 27b of the thermoelectric module 23 is maintained at a relatively low temperature due to the heat dissipation of the heat dissipating fin 24 and the cooling of the cooling fans 15. As a result, it is possible to noticeably increase the temperature difference occurring between the lower substrate 27a and the upper substrate 27b in the thermoelectric module 23, which is thus noticeably increased in the generated electricity. That is, a part of the electric power required for the projector 10 can be covered by the electricity generated by the thermoelectric module 23 which operates based on the recovery of the heat emitted from the lamp 21; thus, it is possible to noticeably reduce the amount of electric power that is required for the projector 10 and is supplied from the power source.

2. Second Embodiment

FIG. 7 shows a lamp 31 and its peripheral parts installed in a projector in accordance with a second embodiment of the invention. This projector is characterized by arranging heat insulating materials 33, made of a glass wool, on side surfaces of the heat absorption member 32. Other parts of the projector of the second embodiment are similar to those of the projector of the first embodiment; hence, the corresponding parts are designated by the same reference numerals.

According to the aforementioned constitution of the projector of the second embodiment, it is possible to reduce the total amount of heat that is leaked from the peripheral surface of the heat absorption member 32 and is not transferred to the thermoelectric module 23; hence, it is possible to perform a further efficient heat conduction with respect to the thermoelectric module 23. As a result, the thermoelectric module 23 can generate a greater amount of electricity. Operations and effects of other parts of the projector of the second embodiment are similar to those of the projector of the first embodiment; hence, the detailed description thereof will be omitted. Incidentally, FIG. 7 shows that the heat insulating materials 33 are attached to only the side surfaces of the heat absorption member 23. Of course, it is possible to modify the second embodiment such that the heat insulating materials 33 are attached to all of the exposed surfaces of the heat absorption member 32, whereby it is possible to make the heat conduction further effective with respect to the thermoelectric module 23.

3. Third Embodiment

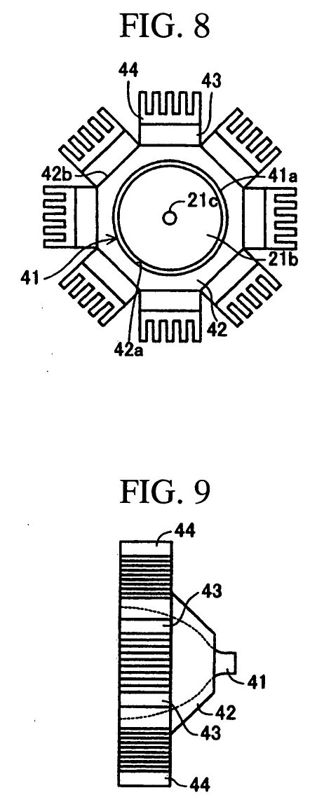

FIGS. 8 and 9 shows a lamp 41 and its peripheral parts installed in a projector in accordance with a third embodiment of the invention. This projector is characterized by arranging a hollow 42a at the center of a heat absorption member 42, thus allowing an exterior wall 41a of the lamp 41 to be inserted therein, wherein the heat absorption member 42 is formed in a cylinder shape whose backend portion is reduced in dimensions. In addition, eight planar portions 42b each having a prescribed area is arranged to adjoin together on the peripheral surface of the front side of the heat absorption member 42, wherein a single thermoelectric module 43 is fixed to each of the planar portions 42b.

Each of the thermoelectric modules 43 respectively fixed to the planar portions 42b of the heat absorption member 42 is equipped with a heat dissipating fin 44. The projector of the third embodiment does not provide the aforementioned heat transfer grease layer, so that the interior wall of the hollow 42a of the heat absorption member 42 comes in direct contact with the exterior wall 41a of the lamp 41. Other parts of the projector of the third embodiment are similar to those of the aforementioned projector 10; hence, the corresponding parts are designated by the same reference numerals.

According to the aforementioned constitution of the projector of the third embodiment, the heat emitted from substantially the entire surface of the exterior wall 41a of the lamp 41 can be effectively transferred to the thermoelectric modules 43 via the heat absorption member 42; hence, it is possible to actualize a further effective heat conduction with respect to the thermoelectric modules 43. As a result, the thermoelectric modules 43 can generate a further increased amount of electricity. Operations and effects of other parts of the projector are similar to those of the aforementioned projector 10; hence, the detailed description thereof will be omitted.

4. Fourth Embodiment

It is possible to realize a fourth embodiment by partially modifying the foregoing embodiment, wherein the lower substrate of the thermoelectric module is made of a heat absorption material (or an heat sink material) which is accompanied with an alumina layer thereon. Herein, the distance between the exterior wall of the lamp and the lower end of the thermoelectric element can be reduced; therefore, it is possible to actualize a further efficient heat conduction with respect to the thermoelectric module.

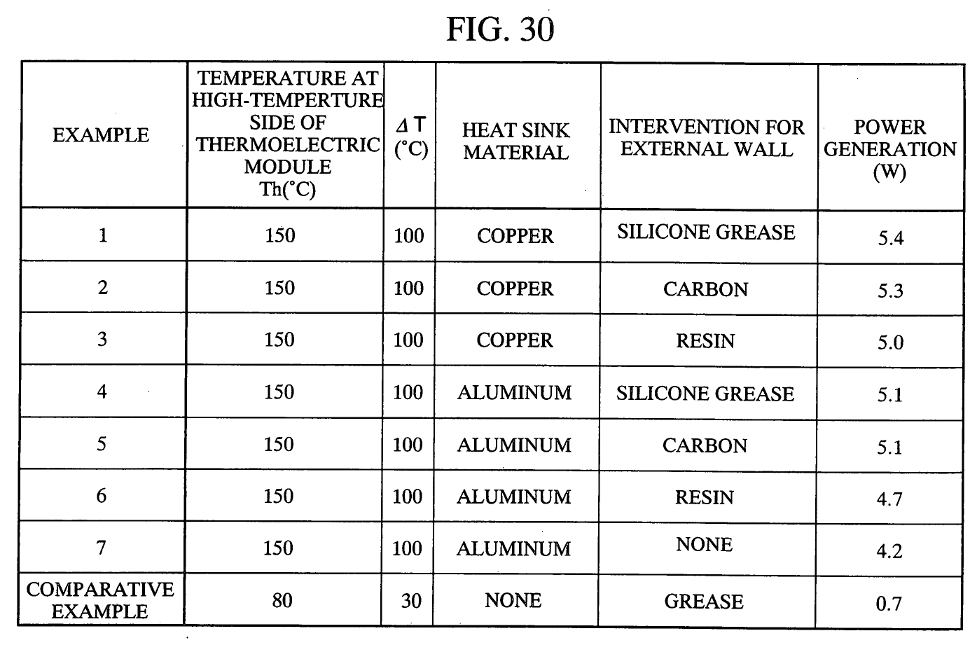

Next, comparative testing is performed on various examples to produce experimental results in comparison with a comparative example in consideration of the foregoing embodiments. Specifically, ‘Example 1’ is created in accordance with the first embodiment that is equipped with the heat absorption member 22 and the heat transfer grease layer 22a as shown in FIGS. 3 and 4, wherein ‘Example 2’ to ‘Example 7’ are created by changing the heat sink material and the thermal resistance reducing material respectively. In addition, ‘Comparative Example’ is created without providing the heat absorption member, wherein the lamp is directly attached to the thermoelectric module by intervention of grease only. Results are shown in FIG. 30.

The aforementioned comparative testing is performed using an extra-high pressure mercury lamp whose electric consumption is 150 W and the thermoelectric module having prescribed dimensions, that is, 20 mm length width and length, and 2 mm height as well as the cooling fan whose electric consumption is 2 W. With respect to each of the Example 1 to Example 7, the temperature difference (identical to the temperature difference between the lower end and upper end of the thermoelectric element) is measured between the upper electrode and the lower electrode that is set to 150° C., and the corresponding electric power generation is measured. With respect to the comparative example, the similar measurement is performed by setting the temperature of the lower electrode at 80° C. in order not to cause destruction of the lamp in consideration of the heat discharge efficiency of the lamp and its safety.

The Example 2 and Example 3 use copper as the heat sink material, while the Example 4 to Example 7 use aluminum as the heat sink material. As the thermal resistance reducing material, the Example 2 uses carbon; the Example 3 uses resin; the Example 4 uses grease; the Example 5 uses carbon; and the Example 6 uses resin, whereas the Example 7 does not provide a thermal resistance reducing layer. As a result, FIG. 30 shows that the temperature difference ΔT between the lower electrode and upper electrode is at 100° C. with respect to all of the Example 1 to Example 7. As the electric power generation, the Example 1 produces 5.4 W; the Example 2 produces 5.3 W; the Example 3 produces 5 W; the Example 4 produces 5.1 W; the Example 5 produces 5.1 W; the Example 6 produces 4.7 W; and the Example 7 produces 4.2 W. In addition, the Comparative Example produces 0.7 W as the electric power generation, wherein the temperature difference ΔT between the lower electrode and upper electrode is 30° C.

As described above (and as shown in FIG. 30), all of the Example 1 to Example 7 can produce a very large amount of electricity compared with that of the Comparative Example. Among them, the examples using copper as the heat sink material can produce a greater amount of electricity compared with the examples using aluminum as the heat sink material. In addition, results can be sequentially improved by using grease, carbon, and resin as the thermal resistance reducing material in turn, wherein the Example 7 not using the thermal resistance reducing material produces the smallest amount of electricity. The aforementioned results indicate that the greatest amount of electricity can be actualized by using copper for the heat absorption member and by using grease for the thermal resistance reducing layer.

5. Fifth Embodiment

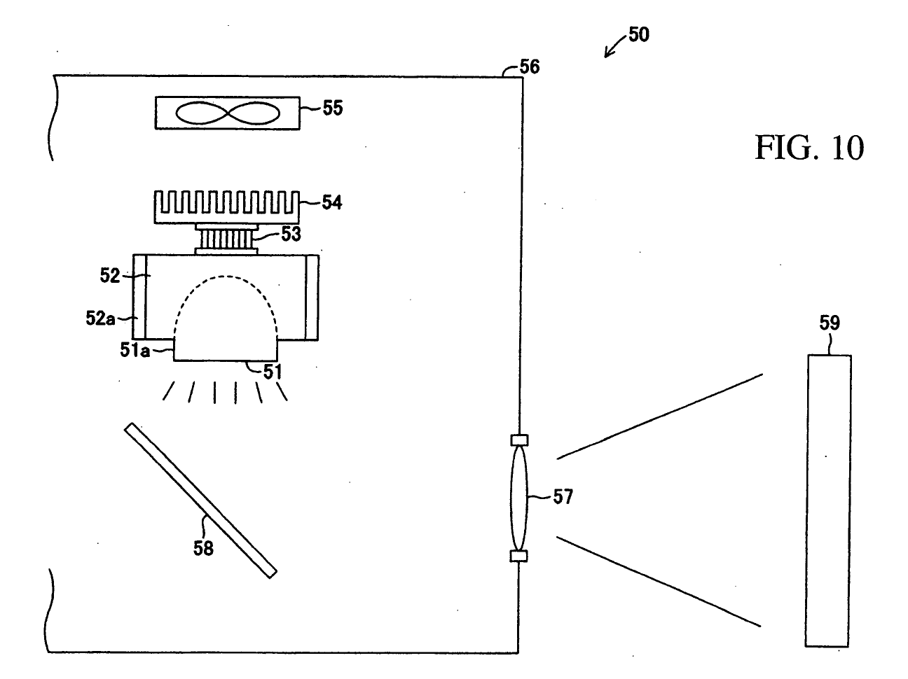

FIG. 10 shows essential parts of a projector 50 that is a thermoelectric generator in accordance with a fifth embodiment of the invention. That is, a projector 50 shown in FIG. 10 comprises a lamp 51, which is directed downwardly and is installed in a box-like housing 56. The upper portion of the lamp 51 is equipped with a heat absorption member 52 on which a thermoelectric module 53 is attached. The heat absorption member 52 is formed as a block made of aluminum in such a way that the upper surface thereof is formed planar, and the lower surface thereof is curved along an exterior wall 51a of the lamp 51 so as to form a hollow. That is, the lamp 51 is fixed into the hollow of the heat absorption member 52 in such a way that the exterior wall 51a comes in contact with the interior wall of the hollow. In addition, heat insulating materials 52a made of glass wool are attached to side surfaces of the heat absorption member 52.

The thermoelectric module 53 whose constitution is identical to the foregoing thermoelectric module 23 is attached onto the upper surface of the heat absorption member 52. In addition, a heat dissipating fin 54 whose constitution is identical to the foregoing heat dissipating fin 24 is attached onto the upper surface of the thermoelectric module 53. Furthermore, a cooling fan 55 is arranged above the heat dissipating fin 54 with a prescribed distance therebetween. That is, the cooling fan 55 is attached to the ceiling of the housing 56 so as to introduce the external air into the housing 56, whereby the heat dissipating fin 54 is cooled so as to increase the temperature difference between the upper substrate and lower substrate of the thermoelectric module 53.

An opening is formed at a prescribed position of the front side of the lower section of the housing 56 and is equipped with a lens 57, which is fixed such that the optical axis thereof lies in a horizontal direction and crosses the optical axis of the lamp 51. A reflection mirror 58 is arranged at the position at which the optical axis of the lamp 51 crosses the optical axis of the lens 57 in such a way that the inclination angle thereof can be freely adjusted. In addition, a screen 59 is arranged outside of the housing 56 with a prescribed distance measured from the lens 57. Other parts of the projector 50 shown in FIG. 10 are similar to those of the foregoing projector 10; hence, the detailed description thereof will be omitted.

According to the projector 50 of the fifth embodiment, the lamp 51 is directed downwardly and is equipped with the heat absorption member 52 in such a way that the exterior wall 51a thereof is entirely brought into contact with the hollow of the heat absorption member 52, wherein the thermoelectric module 53 is attached onto the upper surface of the heat absorption member 52. Therefore, the heat that is emitted from the lamp 51 and moves upwardly can be efficiently absorbed by the heat absorption member 52, from which it is reliably transferred to the thermoelectric module 53, wherein the upper surface of the thermoelectric module 53 is cooled by means of the heat dissipating fin 54 and the cooling fan 55. Hence, it is possible to increase the temperature difference between the upper surface and lower surface of the thermoelectric module 53, which is thus increased in the electric power generated therewith. Operations and effects of other parts of the projector 50 are similar to those of the foregoing projector 10; hence, the detailed description thereof will be omitted.

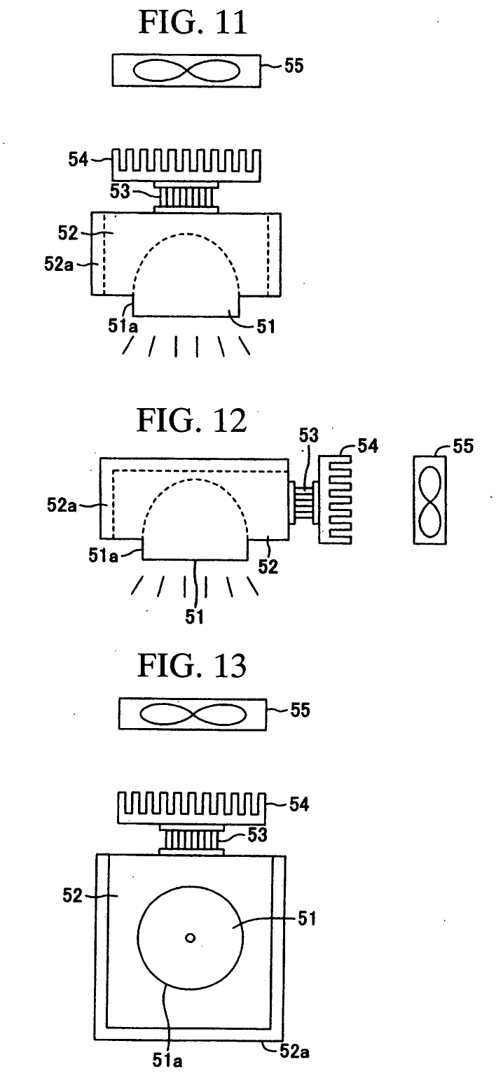

Next, comparison is made with respect to ‘Example 8’, Example 9’, and ‘Example 10’, each of which is created in accordance with the present embodiment. Specifically, the Example 8 is created by providing all of the lamp 51, heat absorption member 52, heat insulating materials 52a, thermoelectric module 53, heat dissipating fin 54, and cooling fan 55 as shown in FIG. 11; the Example 9 is created by partially modifying the Example 8 such that parts 52a and 53-55 are changed in positions as shown in FIG. 12; and the Example 10 is created by partially modifying the Example 8 such that the lamp 51 is changed in light emission direction as shown in FIG. 13. These Examples are compared with each other in terms of the electric power generation.

The Example 9 shown in FIG. 12 is created such that the upper portion of the exterior wall 51a of the lamp 51 that is directed downwardly is covered with the hollow of the heat absorption member 52, and the thermoelectric module 53 is attached to the side surface of the heat absorption member 52, wherein the heat dissipating fin 54 is attached to the thermoelectric module 53 that is directed horizontally, and the cooling fan 55 is arranged relative to the heat dissipating fin 54 with a prescribed distance therebetween. In addition, the heat insulating materials 52a are attached to the upper surface and side surface of the heat absorption member 52 other than its prescribed side surface connected with the thermoelectric module 53.

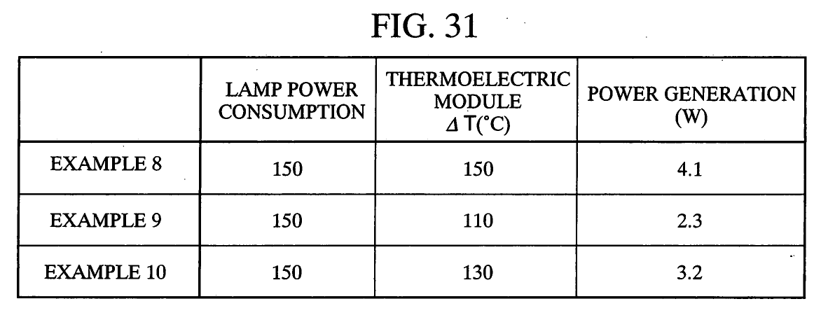

The Example 10 shown in FIG. 13 is created such that the lamp 51 is directed horizontally in the light emission direction, and the heat absorption member 52 is attached to the backend of the exterior wall 51a of the lamp 51. In addition, the thermoelectric module 53 is attached onto the upper surface of the heat absorption member 52, and the heat dissipating fin 54 is attached onto the upper surface of the thermoelectric module 53. Furthermore, the cooling fan 55 is arranged above the heat dissipating fin 54 with a prescribed distance therebetween. The heat insulating materials 52a are arranged on the exterior surfaces of the heat absorption member 52 other than its upper surface and front surface. Incidentally, none of the Example 8 to Example 10 provides the heat transfer grease layer. FIG. 31 shows testing results regarding comparison of electric power generation between the Example 8, Example 9, and Example 10.

The aforementioned testing is performed using an extra-high pressure mercury lamp whose electric consumption is 150 W, and the thermoelectric module having prescribed dimensions, that is, 40 mm width and length, and 3 mm height, as well as the cooling fan whose electric consumption is 2 W. That is, the Example 8 to Example 10 are subjected to measurement in terms of the temperature difference ΔT between the upper electrode and lower electrode as well as the electric power generation under the condition where the temperature at the upper electrode (corresponding to the heat radiating side of the thermoelectric module 53) is set to 50° C. Results are shown in FIG. 31, which indicates that the temperature difference ΔT between the lower electrode and upper electrode is 150° C. in the Example 8, 110° C. in the Example 9, and 130° C. in the Example 10. In addition, the electric power generation is 4.1 W in the Example 8, 2.3 W in the Example 9, and 3.2 W in the Example 10.

As described above, the Example 8 in which the lamp 51 is directed downwardly in the light emission direction, and the heat absorption member 52 and thermoelectric module 53 are arranged above the lamp 51 can produce a greater amount of electricity compared with the Example 9 and Example 10. The next place following the Example 8 is the Example 10, which produces a great amount of electricity compared with the Example 9 and in which the lamp 51 is directed horizontally in the light emission direction, and the heat absorption member 52 and thermoelectric module 53 are arranged above the lamp 51. That is, in order to produce a relatively large amount of electricity, it is preferable to arrange the heat absorption member 52 and thermoelectric module 53 above the lamp 51; and it is preferable to set the light emission direction of the lamp 51 downwardly so that the heat radiating direction of the lamp 51 is directed upwardly.

6. Sixth Embodiment

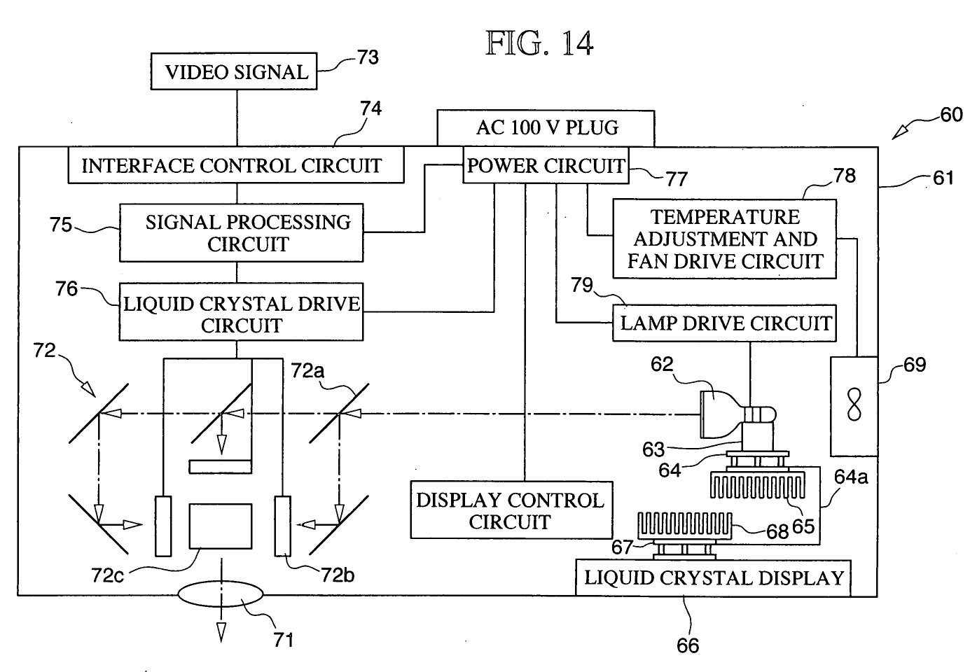

FIG. 14 shows the outline of the constitution of a projector 60 that is a thermoelectric generator in accordance with a sixth embodiment of the invention. In the projector 60, a lamp 62 is directed horizontally in the light emission direction and is arranged inside of a box-like housing 61. A heat absorption member 63 is attached to the lower surface of the backend portion of the lamp 62, and a thermoelectric module 64 is attached to the lower portion of the heat absorption member 63. The heat absorption member 63 is formed like a block made of aluminum in that the upper surface thereof is curved to match the ‘curved’ lower surface of the backend portion of the lamp 62, and the lower surface thereof is made planar.

A heat dissipating fin 65 is attached to the lower surface of the thermoelectric module 64 attached to the lower surface of the heat absorption member 63. A display 66 is arranged under the lamp 62 inside of the housing 61 such that the screen thereof is exposed to the exterior of the housing 61, wherein a Peltier element 67 is attached to the upper surface of the display 66. The Peltier element 67 is connected with the thermoelectric module 64 via a lead 64a, so that it cools the display 66 by use of the electric power supplied thereto from the thermoelectric module 64. A heat dissipating fin 68 is attached to the upper surface of the Peltier element 67 as well. A cooling fan 69 is arranged in the backside of the lamp 62 and is attached to the interior wall of the housing 61.

An opening is formed at a prescribed position of the lower surface of the housing 61, and a lens 71 is attached to the opening of the housing 61 in such a way that the optical axis thereof lies in a vertical direction and crosses with the optical axis of the lamp 62. An optical system 72 is arranged at a prescribed position at which the optical axis of the lamp 62 crosses the optical axis of the lens 71. The optical system 72 comprises a split optical device 721a including a plurality of mirrors, a plurality of liquid crystal panels 72b, and a composite optical device 72c, whereby the liquid crystal panels 721b are illuminated by the light projected from the lamp 62 so that images thereof are projected onto a screen (not shown) via the lens 71.

The projector 60 can be connected with an external device (not shown), wherein it comprises an interface control circuit 74 for receiving video signals 73 from the external device, a signal processing circuit 75 for performing various signal processings realizing high-quality video processing and the like, and a liquid crystal drive circuit 76 for operating the liquid crystal panels 72b. In addition, it also comprises a power source circuit 77, a temperature adjustment and fan drive circuit 78, and a lamp drive circuit 79 for driving the lamp 62.

As described above, the projector 60 of the sixth embodiment is characterized by that the lamp 62 is directed in a horizontal direction, and the heat absorption member 63 is attached to the lower surface of the backend portion of the lamp 62. In addition, the thermoelectric module 64 is attached to the lower surface of the heat absorption member 63. Thus, it is possible to supply the Peltier element 67 with a certain electric power, which is sufficient to cool the liquid crystal display 66. Operations and effects of other parts of the projector 60 are similar to those of the foregoing projector 10; hence, the detailed description thereof will be omitted.

The thermoelectric generator of this invention is not necessarily limited to the aforementioned embodiments; hence, it is possible to adequately modify them within the scope of the invention. For example, the first, second, and third embodiments respectively use the heat absorption members 22, 32, and 42, each of which is made of the touch pitch copper. Of course, it is possible to use other materials such as oxygen free copper and aluminum for the formation of the heat absorption member. Herein, it is preferable to use pure aluminum by which the heat conductivity can be increased and the overall weight of the projector can be reduced. The second and fifth embodiments are constituted such that the heat absorption members 32 and 52 are coated with the heat insulating materials 33 and 52a, each of which is made of the glass wool. Of course, it is possible to use other heat insulating materials such as rock wool rather than the glass wool.

In addition, it is possible to replace the heat transfer grease layer, which is arranged in the boundary between the exterior wall 21a of the lamp 21 and the heat absorption member 22, with the carbon layer and resin layer, for example. Alternatively, it is possible not to provide the heat dissipating layer in the boundary between the lamp and the heat absorption member. Furthermore, this invention can be directed to any types of thermoelectric generators, which are not necessarily limited to the projectors, as well as other apparatuses in which lamps produce heat. For example, this invention can be applied to outdoor lighting systems, indoor lighting systems, automobiles, motorcycles, and the like, each of which is equipped with lights. The display 26 is not necessarily limited to the device in which a plurality of small metal mirrors are arranged on a silicone substrate; hence, it is possible to use a liquid crystal device for use in the display 26.

7. Seventh Embodiment

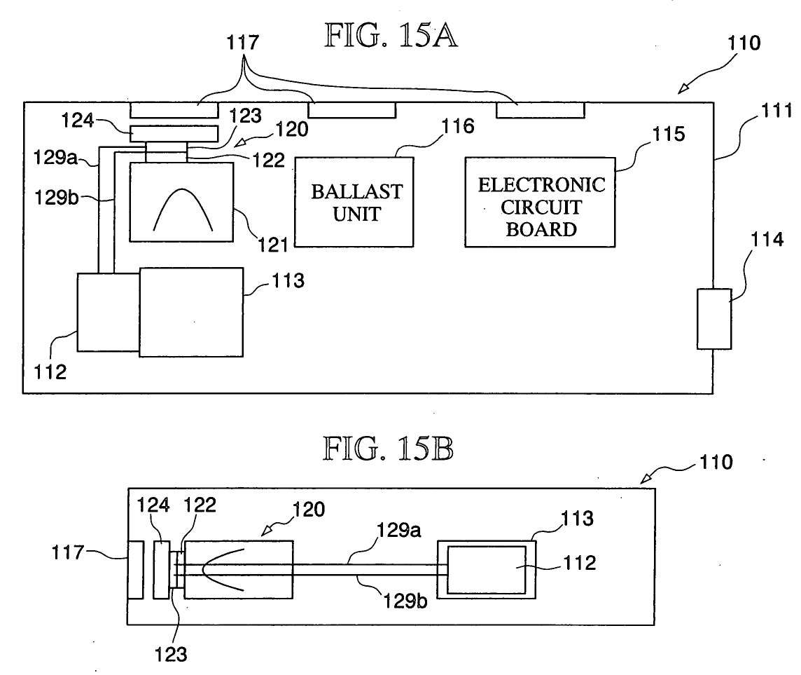

FIGS. 15A and 15B show a projector 110 equipped with a thermoelectric generator 120 in accordance with a seventh embodiment of the invention. The projector 110 comprises the thermoelectric generator 120, a Peltier element 112, a display 113, a lens 114, an electronic circuit board 115, a ballast unit 116, and cooling fans 117, all of which are incorporated into a box-like housing 111.

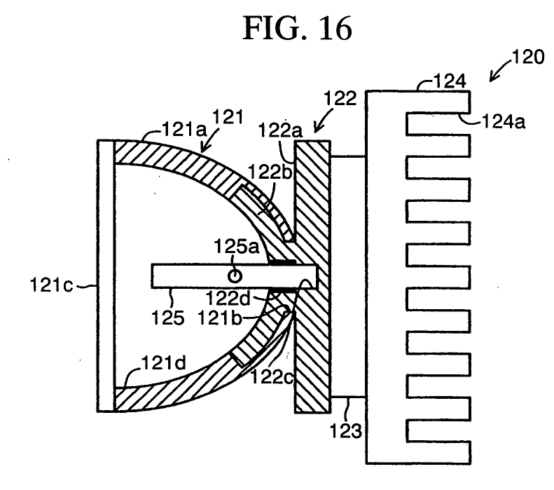

As shown in FIG. 16, the thermoelectric generator 120 comprises a lamp 121, a heat absorption member 122, a thermoelectric module 123, and a heat dissipating fin 124. An exterior wall 121a forming a reflector for the lamp 121 is constituted as a dome-like ceramic body in which the front portion thereof provides a circular opening, and the side portion thereof is gradually reduced in dimensions towards the backend portion thereof. A hole 121b is formed at the center of the backend portion of the exterior wall 121a, by which a communication is secured from the inside to the outside with respect to the lamp 121. The hole 121b is formed like a concave that is broadened like a dome along the interior surface of the exterior wall 121a towards the front portion thereof.

A transparent glass 121c is attached to the opening of the exterior wall 121a at its front portion, and a light emitting tube 125 is arranged at the center of the backend portion of the exterior wall 121a. The light emitting tube 125 is arranged in such a way that the backend portion thereof is positioned at the center of the hole 121b of the exterior wall 121 a, and the front portion thereof is extended towards the center of the glass 121c, wherein a light source 125a serving as a heating element is incorporated in the center portion of the light emitting tube 125. Specifically, the light emitting tube 125 is constituted by an extra-high pressure mercury lamp, wherein when it is turned on, the internal pressure becomes 200 units of the atmospheric pressure or so, and the temperature in proximity of the light source 125a is increased to 1000° C. or so. Herein, the temperature of the exterior wall 121a is increased to 220° C. or so.

The heat absorption member 122 is arranged at the backend portion of the lamp 121 and is made of touch pitch copper. The heat absorption member 122 is constituted by a planar portion 122a and a projecting portion 122b, wherein the center portion of the planar portion 122a is positioned at the backend portion of the lamp 121 such that the longitudinal side of the planar portion 122a stands in a vertical direction, and the projecting portion 1221b projects from the center of the front side of the planar portion 122a so as to penetrate through the hole 121b of the exterior wall 121a and is partially arranged inside of the lamp 121.

In addition, a hole 122c is formed to penetrate through the center of the projecting portion 1221b and the center of the planar portion 122a of the heat absorption member 122 in its front side. Hence, the backend portion of the light emitting tube 125 is fixed inside of the hole 122c of the heat absorption member 122. Furthermore, an adhesive layer 122d made of a prescribed adhesive having a heat resistance is formed in a gap between the interior peripheral surface of the hole 122c formed in the projecting portion 1221b of the heat absorption member 122 and the exterior peripheral surface of the light emitting tube 125. The touch pitch copper forming the heat absorption member 122 has a relatively high heat conductivity; therefore, it is possible to efficiently absorb the heat emitted from the light source 125a by means of the projecting portion 1221b of the heat absorption member 122 that is broadened like a dome in proximity to the light source 125a inside of the lamp 121.

The heat emitted from the exterior peripheral surface of the exterior wall 121a can be absorbed by the planar portion 122a of the heat absorption member 122. A reflection surface 121d is formed by deposition (or evaporation) of aluminum and is extended to cover the interior peripheral surface of the exterior wall 121a and the exposed surface of the projecting portion 122b of the heat absorption member 122. The light emitting tube 125 is equipped with an electric terminal (not shown), which is connected with a power source via a wire.

The thermoelectric module 123 is constituted as similar to the foregoing thermoelectric module 23 shown in FIGS. 5 and 6, wherein thermoelectric elements 128 are connected between a lower substrate 126a having lower electrodes 127a and an upper substrate 126b having upper electrodes 127b by solder, wherein the lower electrodes 127a are connected with leads 129a and 129b, by which communication is established with respect to an external device and the like.

In the above, each of the lower substrate 126a and the upper substrate 126b is constituted by an alumina plate, and each of the thermoelectric elements 128 is constituted by a bismuth-tellurium alloy having a rectangular parallelopiped shape in correspondence with a p-type element or an n-type element. In general, thermoelectric materials greatly differ from each other in performance indexes, wherein they have specific temperature dependent properties and differ from each other in the temperature indicating the maximal value; therefore, it is preferable to use bismuth-tellurium alloys as thermoelectric materials for use in public consumer' products such as illuminations and projectors whose used temperatures range from 500 K to 600 K, wherein an alloy of Bi_{0.5}Sb_{1.5}Te₃ can be used for the p-type element, and an alloy of Bi₂Sb_{2.8}Se_{0.2} can be used for the n-type element, for example.

The aforementioned thermoelectric elements 128 are connected in series via the lower electrodes 127a and upper electrode 127b between the lower substrate 126a and the upper substrate 126b. The lower substrate 126a of the thermoelectric module 123 is fixed to the heat absorption member 122, whereby a part of the heat caused by the light emission of the lamp 121 is transmitted to the thermoelectric module 123 via the heat absorption member 122. That is, the thermoelectric module 123 generates electricity based on the temperature difference between the lower substrate 126a, which is heated by the heat emitted from the lamp 121, and the upper substrate 126b.

The heat dissipating fin 124 is formed as an aluminum block whose backend portion provides a plurality of heat dissipating grooves 124a, which are elongated in front-back directions and are arranged at prescribed distances therebetween, wherein it is fixed to the upper substrate 127b of the thermoelectric module 123. The heat dissipating fin 124 is designed to improve the heat dissipating ability by increasing the overall surface area of the backend portion thereof due to the provision of a plurality of heat dissipating grooves 124a, whereby it is possible to increase the amount of heat released therefrom with respect to the upper substrate 127b of the thermoelectric module 123. Thus, it is possible to noticeably increase the temperature difference between the lower substrate 126a and the upper substrate 126b in the thermoelectric module 123, which is thus increased in the electric power being generated therewith.

The ends of the leads 129a and 129b extended from the thermoelectric module 123 are connected with the Peltier element 112 for cooling the display 113. The Peltier element 112 is constituted as similar to the thermoelectric module 123; therefore, it can convert the electricity supplied thereto from the thermoelectric module 123 via the leads 129a and 129b into the heat. In the present embodiment, the Peltier element 112 is used for cooling the display 113.

The display 113 is constituted by a device in which a plurality of small metal mirrors are arranged on a silicon substrate, wherein incoming light is controlled in reflecting directions therefor so that the reflected light is transmitted to the lens 114, thus projecting an image on a screen (not shown). The display 113 may not operate normally and will be reduced in lifetime; hence, it should be cooled by the Peltier element 112.

An image processing circuit and the like are arranged on the electronic circuit board 115 installed in the housing 111. The ballast unit 116 provides a stabilizer by which a constant electric power is normally supplied to the lamp 121, regardless of fluctuations of the electric power supplied to the projector 110. Thus, the lamp 121 can emit light in a stable manner. The cooling fans 117 are arranged at several openings (not shown) formed at prescribed positions of the housing 111, whereby the external air is introduced into the housing 111 whose components are thus subjected to air cooling.

Other than the aforementioned devices and components, the projector 110 of the present embodiment further provides a power source for supplying the electric power to the components arranged therein, a variety of switches and operation buttons, and input/output terminals allowing video data and audio data to be inputted thereto or to be outputted therefrom with respect to an external device such as a personal computer.

In order to use the projector 110 having the aforementioned constitution, a plug or a connector of a wiring cord of an external device (e.g., a personal computer) is connected with the input/output terminals, thus allowing transmission and reception of data and signals. Then, the user (or human operator) turns on a power switch and operates the operation button(s). Thus, the lamp 121 is turned on to emit light, and the display 113 and the prescribed components of the projector 110 are activated so that a prescribed image is projected onto the screen via the lens 114.

In this case, the internal temperature of the housing 111 increases due to the heat caused by the light emission of the lamp 121 and the heat generated by various components of the projector 110 such as the display 113, whereas the cooling fans 117 operate to control the air flow inside of the housing 111, which is thus subjected to air cooling. At this time, the heat emitted from the exterior peripheral surface of the lamp 121 is transmitted to the planar portion 122a of the heat absorption member 122, while a part of the heat emitted from the interior peripheral surface of the exterior wall 121a is absorbed by the projecting portion 1221b of the heat absorption member 122, which is transferred to the planar portion 122a and is then further transferred to the upper substrate 126b of the thermoelectric module 123.

The projecting portion 1221b of the heat absorption member 122 is well broadened in area along the interior peripheral surface of the exterior wall 121a; hence, the heat absorption and conduction can be actualized efficiently. In addition, the lower substrate 126a of the thermoelectric module 123 is cooled by the heat dissipating function of the heat dissipating fin 124 and is also subjected to air cooling due to the air flow caused by the cooling fans 117.

As a result, it is possible to produce a relatively large temperature difference between the end portion of the lower substrate 126a and the end portion of the upper substrate 126b in the thermoelectric module 123, which in turn generates a relatively great amount of electricity. The electric power generated by the thermoelectric module 123 is supplied to the Peltier element 112, which is thus activated to cool the display 113.

With reference to FIGS. 5 and 6 (which are arranged for illustrating the constitution of the thermoelectric module 23 corresponding to the thermoelectric module 123), the aforementioned Peltier element 112 will be described in detail. Suppose that a thermoelectric element 128 connected with the lead 129a serves as an n-type element, and a thermoelectric element 128 connected with the lead 129b serves as a p-type element, wherein a positive voltage is applied to the lead 129a, and a negative voltage is applied to the lead 129b, so that the upper substrate 126b acts as a heat absorption side, and the lower substrate 126a acts as a heat radiation side. Therefore, the Peltier element 112 is arranged in such a way that the upper substrate thereof is brought into contact with the display 113, which is thus cooled. That is, the display 113 is maintained at an appropriate temperature so as to realize a good picture quality, and it can be increased in the lifetime thereof. Herein, the arrangement directions of the thermoelectric module 123 and the Peltier element 112 can be adequately changed in response to the arrangement of the p-type element and n-type element and the connections with the leads 129a and 129b.

According to the seventh embodiment, the projector 110 having the thermoelectric generator 120 is characterized by providing the heat absorption member 122 having a superior heat conductivity between the thermoelectric module 123 and the lamp 121, wherein the projecting portion 1221b of the heat absorption member 122 is introduced into the exterior wall 121a of the lamp 121 and is broadened in area along the interior peripheral surface of the exterior wall 121a. Therefore, the heat absorption member 122 can absorb not only the heat emitted from the exterior peripheral surface of the exterior wall 121a of the lamp 121 but also the high-temperature heat emitted inside of the exterior wall 121a of the lamp 121, so that both heat can be reliably transferred to the upper substrate 126b of the thermoelectric module 123.

The lower substrate 126a of the thermoelectric module 123 is substantially maintained at a relatively low temperature due to the heat dissipating function of the heat dissipating fin 124 and the air cooling of the cooling fans 117. As a result, it is possible to increase the temperature difference between the lower substrate 126a and the upper substrate 126b in the thermoelectric module 123, which is thus increased in the electric power being generated therewith. That is, a part of the electric power required for the projector 110 can be covered with the electricity that is generated using the waste heat emitted from the lamp 121; hence, it is possible to reduce the total amount of electricity consumed in the projector 110.

8. Modifications

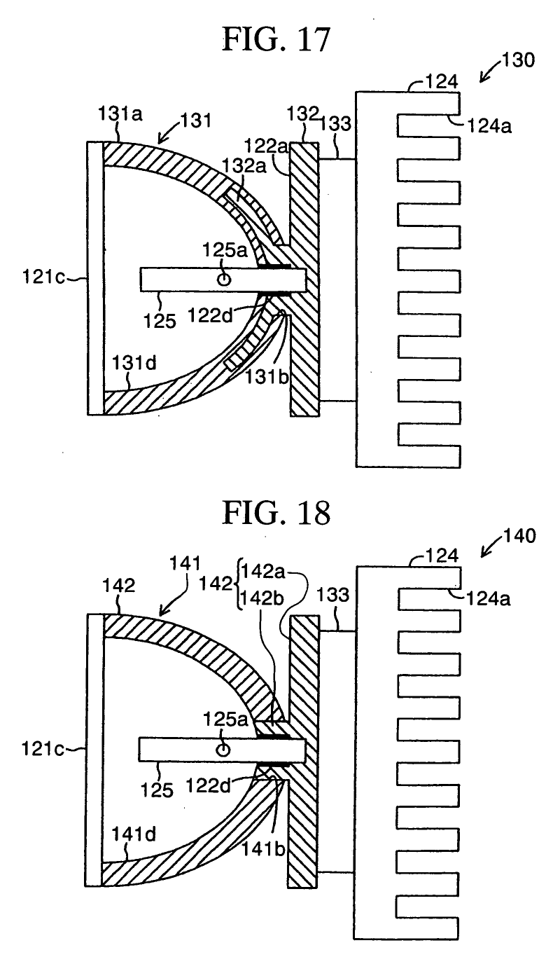

It is possible to modify the aforementioned thermoelectric generator 130 in a variety of ways, which will be described with reference to FIGS. 17 to 20. FIG. 17 shows a thermoelectric generator 130 that can be adopted in the automobile's light and is attached to the front portion of the body of the automobile, for example. The thermoelectric generator 130 is characterized in that a hole 131b is not formed to reach the interior peripheral surface of an exterior wall 131a of a lamp 131 but is broadened like a dome formed between the interior peripheral surface and the exterior peripheral surface of the exterior wall 131a of the lamp 131. For this reason, a projecting portion 1321b of a heat absorption member 132 is tightly enclosed inside of the hole 131b within the exterior wall 131a of the lamp 131, wherein a reflection surface 131d is formed to entirely cover the interior peripheral surface of the exterior wall 131a of the lamp 131.

In the thermoelectric generator 130, a thermoelectric module 133 attached to the heat absorption member 132 is connected with a battery (not shown), so that the electric power generated by the thermoelectric module 133 is used for charging the battery. The thermoelectric generator 130 shown in FIG. 17 is constituted similar to the aforementioned thermoelectric generator 120 except that it has specific shaping and is increased in the electric power consumption; hence, the corresponding parts thereof are designated by the same reference numerals.

The thermoelectric generator 130 is characterized by that the projecting portion 1321b of the heat absorption member 132 is not exposed to the interior peripheral surface of the exterior wall 131a; therefore, it becomes easy to form the reflection surface 131d along the interior peripheral surface of the exterior wall 131a of the lamp 131, which is not badly affected in illumination effects. In addition, the projecting portion 1321b of the heat absorption member 132 can be elongated close to the light source 125a, around which it is broadened in area; hence, it is possible to actualize the effective heat conduction towards the thermoelectric module 133, which is thus increased in the electric power being generated therewith.

FIG. 18 shows a thermoelectric generator 140, which can be adopted in the automobile. The thermoelectric generator 140 is characterized in that a hole 141b formed to penetrate through an exterior wall 141a of a lamp 141 does not have a dome-like portion but is merely formed as a circular hole. Hence, a heat absorption member 142 equipped with the lamp 141 comprises a planar portion 142a and a projecting portion 142b having a cylindrical shape. In addition, a reflection surface 141d is formed to cover the interior peripheral surface of the exterior wall 141a of the lamp 141 and the exposed surface of the projecting portion 142b of the heat absorption member 142.

Other parts of the thermoelectric generator 140 are similar to those of the aforementioned thermoelectric generator 130; hence, the corresponding parts thereof are designated by the same reference numerals. In the thermoelectric generator 140, the projecting portion 142b of the heat absorption member 142 is elongated close to the light source 125a; hence, it is possible to actualize the effective heat conduction towards the thermoelectric module 133, which is thus increased in the electric power being generated therewith.

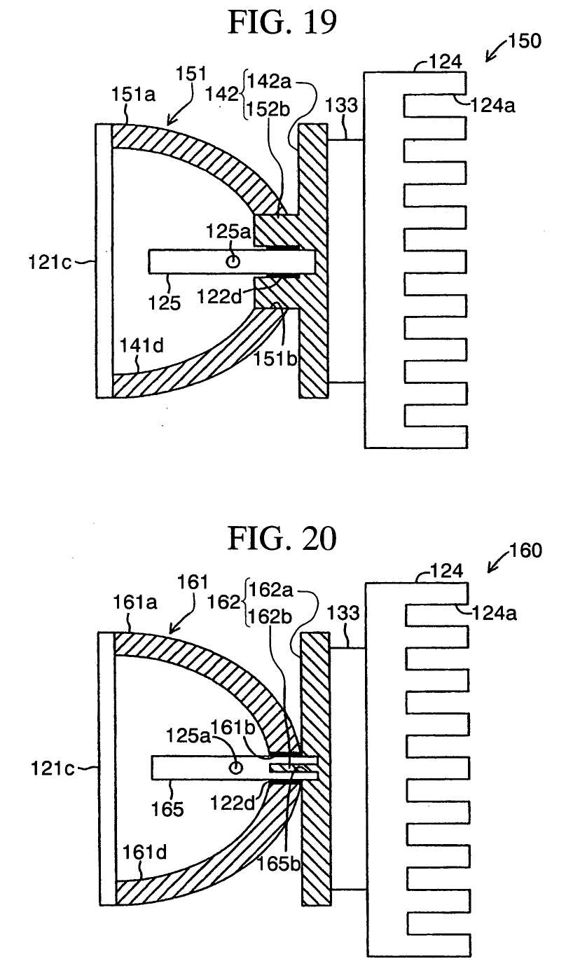

FIG. 19 shows a thermoelectric generator 150, wherein compared with the projecting portion 142b of the heat absorption member 142 installed in the thermoelectric generator 140 shown in FIG. 18, a projecting portion 152b of a heat absorption member 152 is further increased in dimensions so that it is projected in the interior peripheral surface of an exterior wall 151a of a lamp 151. That is, the diameter of a hole 151b formed to penetrate through the exterior wall 151a is increased to be greater than the diameter of the hole 141b formed in the exterior wall 141a shown in FIG. 18. Other parts of the thermoelectric generator 150 are similar to those of the thermoelectric generator 140 shown in FIG. 18; hence, the corresponding parts thereof are designated by the same reference numerals. In short, the thermoelectric generator 150 is characterized in that the projecting portion 152b is elongated towards the high-temperature area proximate to the light source 125a and is further increased in the exposed area thereof; hence, it is possible to actualize a further effective heat conduction towards the thermoelectric module 133, which is thus further increased in the electric power being generated therewith.

FIG. 20 shows a thermoelectric generator 160, wherein a hole 161b formed to penetrate through an exterior wall 161a of a lamp 161 is minimized in dimensions to support the backend portion of a light emitting tube 165, which provides a hole 165b horizontally elongated therein. Correspondingly, a heat absorption member 162 comprises a planar portion 1621a and a rod-like projecting portion 162b, which is elongated in a forward direction from the center of the planar portion 1621a and is inserted into the hole 165b. Therefore, a reflection surface 161d is formed to entirely cover the interior peripheral surface of the exterior wall 161a.

Other parts of the thermoelectric generator 160 are similar to those of the thermoelectric generator 150; hence, the corresponding parts thereof are designated by the same reference numerals. In short, the thermoelectric generator 160 is characterized by that the projecting portion 1621b of the heat absorption member 162 is arranged inside of the light emitting tube 165 serving as a heat source, wherein the tip end thereof is elongated close to the light source 125a. Thus, it is possible to transfer the high-temperature heat directly towards the thermoelectric module 133, which is thus further increased in the electric power being generated therewith.

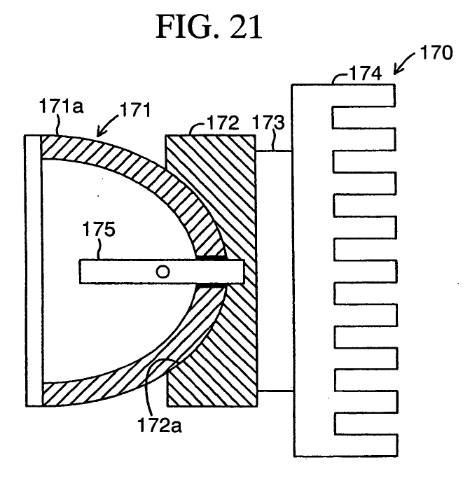

There is also provided a thermoelectric generator 170 shown in FIG. 21, which is used as a comparative example with respect to the aforementioned thermoelectric generator 120 shown in FIG. 16. In the thermoelectric generator 170, an exterior wall 171a of a lamp 171 is formed similar to the exterior wall 161a of the lamp installed in the thermoelectric generator 160 shown in FIG. 20, and a light emitting tube 175 is formed similar to the aforementioned light emitting tube 125 shown in FIGS. 16-19. In addition, a heat absorption member 172 is designed such that the front surface thereof is curved to provide a concave 1721a to match the ‘curved’ backend portion of the exterior wall 171a, whereby it is possible to increase the contact area between the heat absorption member 172 and the exterior wall 171a of the lamp 171. Furthermore, the thermoelectric generator 170 is equipped with a thermoelectric module 173, similar to the aforementioned thermoelectric modules 123 and 133, and a heat dissipating fin 174 similar to the aforementioned heat dissipating fin 124.

In the comparative testing, an extra-high pressure mercury lamp whose electric power consumption is 160 W is used as the lamps 121 and 171 respectively, and a thermoelectric module having prescribed dimensions, that is, 50 mm length and width, and 5 mm height, is used as the thermoelectric modules 123 and 173 respectively. In addition, the overall surface area of each of heat dissipating fins 124 and 174 is set to 0.3 m², and axial-flow cooling fans whose electricity consumption is 2.0 W are used to cool the heat dissipating fins 124 and 174. Furthermore, the heat absorption member 172 is shaped like a block made of touch pitch copper, as shown in FIG. 21, which has prescribed dimensions, that is, 70 mm length and width, and 20 mm thickness, while the heat absorption member 122 is designed such that the planar portion 122a has thickness of 5 mm.

In testing, the aforementioned thermoelectric generator 120 recovers the heat of 80 W from the lamp 121 so as to generate electricity of 4.0 W The thermoelectric generator 170 recovers the heat of 50 W from the lamp 171 so as to generate electricity of 2.0 W. The testing results indicate that the amount of recovered heat can be increased by arranging the projecting portion 1221b of the heat absorption member 122 inside of the lamp 121 in accordance with the constitution of the thermoelectric generator 120, rather than increasing the contact area between the lamp 171 and the heat absorption member 172, which is processed as shown in FIG. 21 in accordance with the constitution of the thermoelectric generator 170. That is, the constitution of the thermoelectric generator 120 increases the electric power generated therewith.

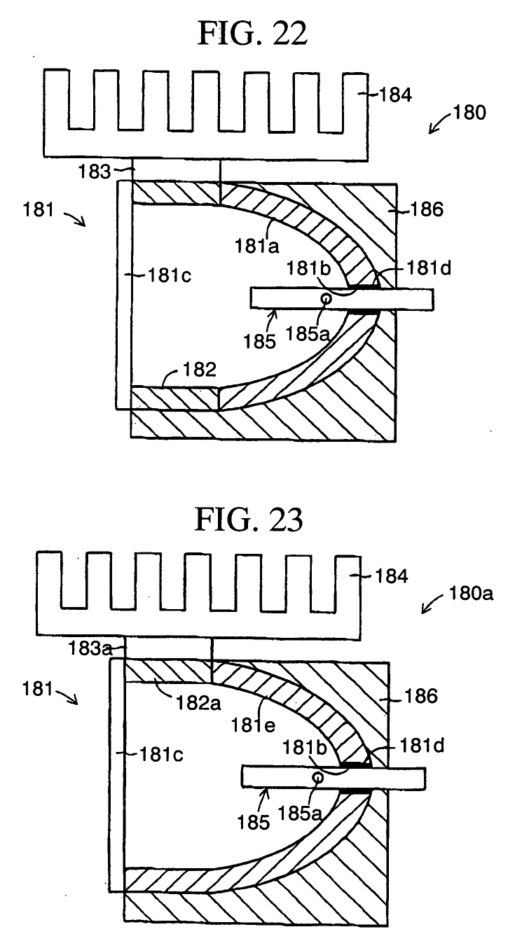

Next, further modified examples of thermoelectric generators will be described with reference to FIGS. 22 to 29. FIG. 22 shows a thermoelectric generator 180 that comprises a lamp 181, a heat absorption member 182, a thermoelectric module 183, a heat dissipating fin 184, a heat insulating material 186, and a fan (not shown) for releasing the heat from the heat dissipating fin 184. The lamp 181 is directed horizontally in the light emission direction thereof, wherein it comprises a dome-like exterior wall 181a in which a hole 181b is formed at the center of the backend portion, a light emitting tube 185 incorporating a light source 185a, and a transparent glass 181c.

The light emitting tube 185 is arranged such that the backend portion thereof is positioned at the hole 181b of the exterior wall 181a, and it is elongated towards the center of the glass 181c in the forward direction. An adhesive layer 181d having a heat resistance is formed in a gap between the interior peripheral surface of the hole 181b and the exterior peripheral surface of the light emitting tube 185; therefore, the light emitting tube 185 is fixed to the hole 181b of the exterior wall 181a via the adhesive layer 181d. The heat absorption member 182 is made of touch pitch copper and is formed like a shortened cylinder whose axial length is shortened, wherein it is arranged between the glass 181c and the opening periphery of the exterior wall 181a. That is, the heat absorption member 182 forms the front portion of the exterior wall 181a.

The thermoelectric module 183 is arranged above the heat absorption member 182. In addition, the prescribed area of the exterior peripheral surface of the heat absorption member 182, which is not accompanied with the thermoelectric module 183, and the other exterior peripheral surface of the exterior wall 181a are covered with the heat insulating material 186. Furthermore, the heat dissipating fin 184 is attached to the upper surface of the thermoelectric module 183; and the aforementioned fan is arranged above the heat dissipating fin 184.

The aforementioned thermoelectric generator 180 of FIG. 22 is characterized by that the heat absorption member 182 forms a part of the exterior wall 181a of the lamp 181, whereby it is possible to directly absorb the heat emitted from the light emitting tube 185. That is, it is possible to actualize the effective heat conduction from the light emitting tube 185 to the heat absorption member 182, from which a relatively large amount of heat can be transferred to the thermoelectric module 183. Due to the provision of the heat dissipating fin 184 and the fan both arranged above the thermoelectric module 183, it is possible to noticeably increase the temperature difference between the lower surface and upper surface of the thermoelectric module 183, which is thus increased in the electric power generated therewith.

In the thermoelectric generator 180 shown in FIG. 22, the lamp 181 is directed horizontally in the light emission direction thereof; however, it is possible to rearrange the lamp 181 to be directed upwardly or downwardly. That is, by adequately changing the direction of the lamp 181, it is possible to adapt the thermoelectric generator 180 to various types of apparatuses.

FIG. 23 shows a thermoelectric generator 180a, which is designed by partially modifying the thermoelectric generator 180 of FIG. 22 in such a way that the heat absorption member 182 is replaced with a heat absorption member 182a, which is not formed like a cylinder and is arranged only below the lower surface of a thermoelectric module 183a. Specifically, the heat absorption member 1821a is installed in a cutout portion that is formed on the upper side of the front-end portion of an exterior wall 181e. Other parts of the thermoelectric generator 180a are similar to the thermoelectric generator 180; hence, the corresponding parts thereof are designated by the same reference numerals; and the detailed description thereof will be omitted.

The thermoelectric generator 180a makes it easy to attach the heat absorption member 1821a to the exterior wall 181e of the lamp 181, whereby it is possible to reduce the total cost for manufacturing the thermoelectric generator 180a. Operations and effects of other parts of the thermoelectric generator 180a are similar to those of the aforementioned thermoelectric generator 180.

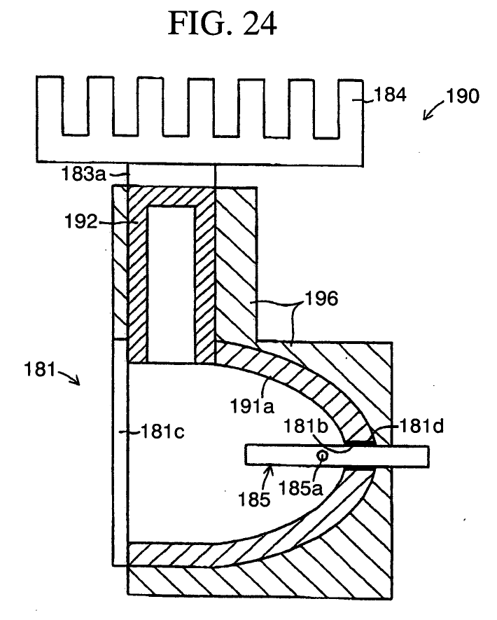

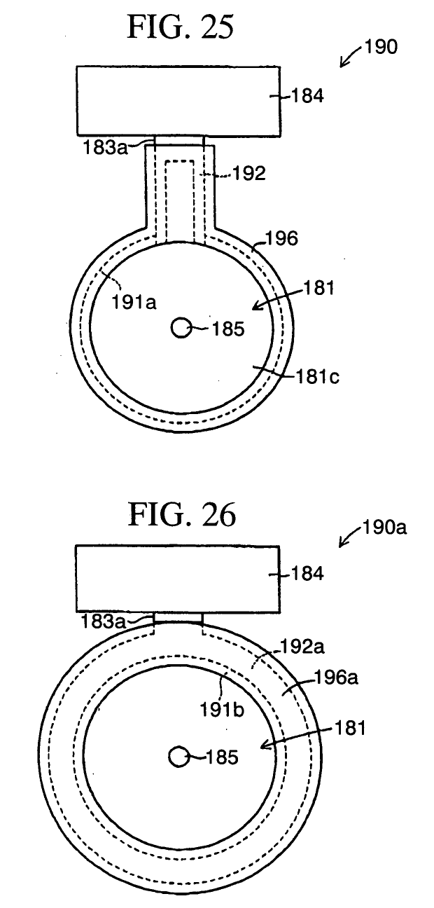

Next, a thermoelectric generator 190 will be described with reference to FIGS. 24 and 25. The thermoelectric generator 190 is characterized by providing a heat absorption member 192 having a longitudinally elongated square box like shape in which the lower surface is opened downwardly, wherein the periphery of the opening of the heat absorption member 192 is attached to a cutout portion formed at the upper side of the front-end portion of an exterior wall 191a. In addition, the exterior peripheral surface of the exterior wall 191a and the exterior peripheral surface of the heat absorption member 192 are covered with heat insulating materials 196. Other parts of the thermoelectric generator 190 are similar to those of the aforementioned thermoelectric generator 180a; hence, the corresponding parts thereof are designated by the same reference numerals.

The thermoelectric generator 190 can increase the total area of the heat absorption member 192 for absorbing the heat emitted from the lamp 181; that is, it is possible to noticeably increase the total amount of heat absorbed by the heat absorption member 192. Thus, it is possible to increase the electric power generated by the thermoelectric module 183a. Operations and effects of other parts of the thermoelectric generator 190 are similar to those of the aforementioned thermoelectric generator 180a.

FIG. 26 shows a thermoelectric generator 190a that is created by partially modifying the thermoelectric generator 190 shown in FIGS. 24 and 25, wherein the thermoelectric generator 190a is characterized providing a heat absorption member 1921a whose cross-sectional shape is similar to that of the heat absorption member 192 of the thermoelectric generator 190, wherein the heat absorption member 1921a is formed like a ring covering the overall circumference of the front portion of an exterior wall 191b. That is, the front portion of the exterior wall 191b is partially removed and is accompanied with the heat absorption member 192. In addition, the exterior peripheral surface of the exterior wall 191b and the exterior peripheral surface of the heat absorption member 1921a are covered with heat insulating materials 196a.

Other parts of the thermoelectric generator 190a are similar to those of the aforementioned thermoelectric generator 190; hence, the corresponding parts are designated by the same reference numerals. According to the modified example shown in FIG. 26, it is possible to further increase the total area of the heat absorption member 1921a for absorbing the heat; that is, it is possible to further increase the total amount of heat absorbed by the heat absorption member 192a. Correspondingly, it is possible to further increase the electric power generated by the thermoelectric module 183a. Operations and effects of other parts of the thermoelectric generator 190a are similar to those of the aforementioned thermoelectric generator 190.

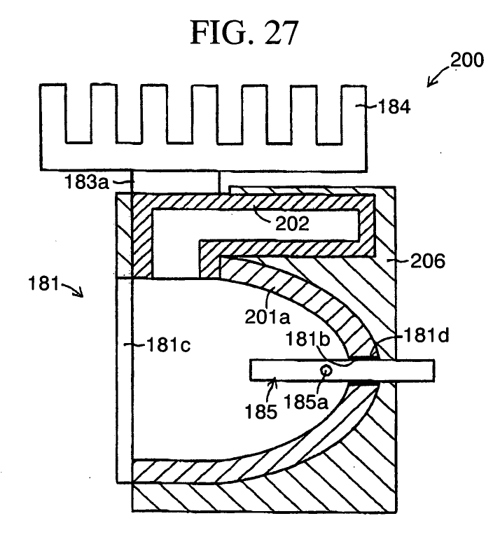

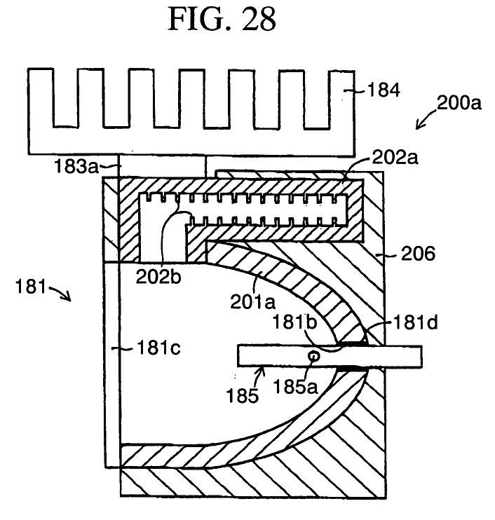

FIG. 27 shows a thermoelectric generator 200, which is characterized in that a heat absorption member 202 is formed like an elongated square box like shape whose front-end portion is opened downwardly, so that the periphery of the opening of the heat absorption member 202 is attached to a cutout portion formed at the upper side of the front-end portion of an exterior wall 201a of the lamp 181. That is, a part of the heat absorption member 202 is arranged to communicate with the cutout portion formed on the upper side of the front-end portion of the exterior wall 201a, wherein the heat absorption member 202 is elongated upwardly so as to realize a box-like shape, which is elongated in a backward direction towards the backend portion of the exterior wall 201a. In addition, the exterior peripheral surface of the exterior wall 201a and the exterior peripheral surface of the heat absorption member 202 are covered with heat insulating materials 206. Other parts of the thermoelectric generator 200 are similar to those of the aforementioned thermoelectric generator 190; hence, the corresponding parts thereof are designated by the same reference numerals.

Although the thermoelectric generator 200 is designed to slightly increase the overall size thereof, it is possible to remarkably increase the overall area of the heat absorption member 202 for absorbing the heat. That is, it is possible to noticeably increase the total amount of heat absorbed by the heat absorption member 202 by controlling the overall size of the thermoelectric generator 200 not to be increased so much; hence, it is possible to noticeably increase the electric power generated by the thermoelectric module 183a. Operations and effects of other parts of the thermoelectric generator 200 are similar to those of the aforementioned thermoelectric generator 190; hence, the detailed description thereof will be omitted. Incidentally, it is possible to further modify the thermoelectric generator 200 such that the overall circumference of the exterior wall 201a is covered with the heat absorption member 202.

FIG. 28 shows a thermoelectric generator 200a, which is created by partially modifying the thermoelectric generator 200 shown in FIG. 27, wherein it is characterized in that a plurality of fins 2021b are arranged at prescribed distances therebetween on the interior peripheral surface of the heat absorption member 202a. Other parts of the thermoelectric generator 200a are similar to the aforementioned thermoelectric generator 200; hence, the corresponding parts are designated by the same reference numerals. Since the thermoelectric generator 200a is designed to increase the total area of the interior peripheral surface of the heat absorption member 202a; hence, it is possible to absorb a further great amount of heat by the heat absorption member 202a. Operations and effects of other parts of the thermoelectric generator 200a are similar to those of the thermoelectric generator 200.

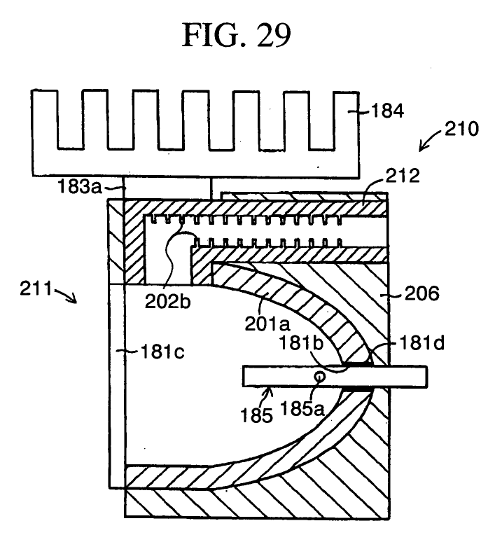

FIG. 29 shows a thermoelectric generator 210, which is created by partially modifying the thermoelectric generator 200a shown in FIG. 28, wherein it is characterized in that the backend of a heat absorption member 212 is opened so that the internal space of a lamp 211 can communicate with the exterior via the internal space of the heat absorption member 212. Other parts of the thermoelectric generator 210 are similar to those of the thermoelectric generator 200a; hence, the corresponding parts thereof are designated by the same reference numerals. Although the thermoelectric generator 210 may slightly reduce to the electric power being generated by the thermoelectric module 183a, it is possible to prevent the internal temperature of the lamp 211 from being increased very high; hence, it is possible to increase the lifetime of the lamp 211. Operations and effects of other parts of the thermoelectric generator 210 are similar to those of the aforementioned thermoelectric generator 200a; hence, the detailed description thereof will be omitted.

Lastly, the thermoelectric generator of this invention is not necessarily limited to the aforementioned embodiment and its modified examples; hence, it is possible to provide a variety of modifications within the scope of the invention. In the aforementioned embodiment, the heat absorption member 122 is made of touch pitch copper; of course, it is possible to use other materials such as oxygen-free copper and aluminum. Herein, it may be preferable to use pure aluminum in order to increase the heat conductivity and to reduce the total weight of the apparatus.

In addition, the lamp 121 is not necessarily limited to the extra-pressure mercury lamp; that is, it is possible to use a metal halide lamp and an incandescent lamp, for example. Furthermore, the exterior wall 121 is not necessarily formed using ceramic, which can be replaced with a glass and the like. The thermoelectric generator of this invention is not necessarily applied to the projector and the automobile but can be applied to a variety of fields regarding apparatuses using lamps generating heat, such as outdoor lighting systems and indoor lighting systems.

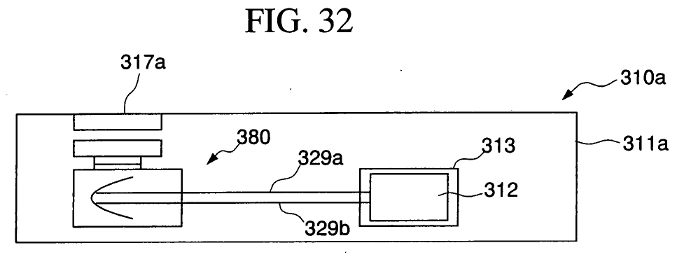

Moreover, the aforementioned projectors can be further modified as shown in FIGS. 32, 33A, and 33B. FIG. 32 shows a projector 310a including a thermoelectric generator 380. This projector 310a comprises a cooling fan 317a arranged on the wall of a housing 311a. The projector 310a further comprises the same components as the aforementioned projector 10 except the constituent elements of the thermoelectric generator 380.

As this invention may be embodied in several forms without departing from the spirit or essential characteristics thereof, the present embodiments are therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

1. A thermoelectric generator comprising:
a thermoelectric module comprising a pair of a first insulating substrate having a plurality of first electrodes and a second insulating substrate having a plurality of second electrodes, between which plural thermoelectric elements are arranged to join the first and second electrodes respectively;
a lamp having an exterior wall including a light emitting tube therein; and
a heat absorption member arranged between a certain portion of the lamp in which temperature rise occurs by heat emitted from the light emitting tube and the first insulating substrate of the thermoelectric module,
wherein the thermoelectric module generates electricity based on a temperature difference between the first insulating substrate, to which heat emitted from the lamp is transferred via the heat absorption member, and the second insulating substrate.

2. A thermoelectric generator comprising:
a thermoelectric module comprising a pair of a first insulating substrate having a plurality of first electrodes and a second insulating substrate having a plurality of second electrodes, between which a plurality of thermoelectric elements are arranged to join the first and second electrodes respectively; and
a heat absorption member that is arranged between the first insulating substrate of the thermoelectric module and an exterior peripheral surface of a lamp,
wherein the thermoelectric module generates electricity based on a temperature difference between the first insulating substrate, which is heated by the lamp via the heat absorption member, and the second insulating substrate.

3. The thermoelectric generator according to claim 2, wherein a first surface of the heat absorption member arranged close to the lamp is shaped to match the exterior peripheral surface of the lamp, while a second surface of the heat absorption member is shaped to match the first insulating substrate of the thermoelectric module.

4. The thermoelectric generator according to claim 2, wherein the first insulating substrate of the thermoelectric module is made of a thin film.

5. The thermoelectric generator according to claim 2, wherein the heat absorption member is made of aluminum or copper.

6. The thermoelectric generator according to claim 2, wherein a thermal resistance reducing layer made of a prescribed material having a relatively high heat resistance or a relatively high thermal conductivity is arranged in a gap between the heat absorption member and the exterior peripheral surface of the lamp.

7. The thermoelectric generator according to claim 6, wherein the prescribed material is selected from among grease, carbon, and resin.

8. The thermoelectric generator according to claim 2, wherein the heat absorption member is coated with a heat insulating material except the first and second surfaces thereof.

9. The thermoelectric generator according to claim 2, which is adapted to a projector.

10. The thermoelectric generator according to claim 2 further comprising:
a display for displaying an image; and
a Peltier element for adjusting temperature of the display, wherein the electricity generated by the thermoelectric module is supplied to the Peltier element to adjust the temperature of the display.

11. The thermoelectric generator according to claim 10, wherein the display comprises a device in which a plurality of small metal mirrors are arranged on a substrate.

12. The thermoelectric generator according to claim 2, wherein the thermoelectric module is arranged above the lamp.

13. The thermoelectric generator according to claim 2, wherein the lamp is directed downwardly in light emission direction.

14. The thermoelectric generator according to claim 2, wherein the heat absorption member is arranged above the lamp so as to transmit heat emitted from the lamp upwardly, and the thermoelectric module is arranged above the heat absorption member so as to receive the heat from the lamp via the heat absorption member.

15. The thermoelectric generator according to claim 2, wherein each of the thermoelectric elements is made of a prescribed material, which is a combination of at least one of bismuth and antimony and at least one of tellurium and selenium.

16. A thermoelectric generator comprising:
a thermoelectric module comprising a pair of a first insulating substrate having a plurality of first electrodes and a second insulating substrate having a plurality of second electrodes, between which a plurality of thermoelectric elements are arranged to join the first and second electrodes respectively;
a lamp having an exterior wall including a light emitting tube therein; and
a heat absorption member that is arranged between the light emitting tube of the lamp and the first insulating substrate of the thermoelectric module, wherein at least a part of the heat absorption member is arranged inside of the lamp.

17. The thermoelectric generator according to claim 16, wherein the thermoelectric module is attached to a backend portion of the lamp by intervention of the heat absorption member, which is brought into contact with the first insulating substrate of the thermoelectric module and the backend portion of the lamp, and wherein the heat absorption member is partially arranged inside of the lamp.

18. The thermoelectric generator according to claim 17, wherein the part of the heat absorption member penetrates through the exterior wall of the lamp and is elongated towards and broadened along an interior peripheral surface of the exterior wall of the lamp.

19. The thermoelectric generator according to claim 17, wherein an internal space is formed inside of the exterior wall of the lamp to encompass the light emitting tube, so that the part of the heat absorption member is elongated inwardly into the internal space.

20. The thermoelectric generator according to claim 17, wherein the part of the heat absorption member is arranged in a boundary between the light emitting tube and a part of an exterior peripheral surface of the exterior wall supporting the light emitting tube.

21. The thermoelectric generator according to claim 20, wherein the part of the heat absorption member penetrates through the exterior wall of the lamp and is arranged inside of the lamp encompassed by the exterior wall.

22. The thermoelectric generator according to claim 17, wherein an internal space is formed inside of the light emitting tube and is elongated from a backend of the light emitting tube to a light source of the light emitting tube.

23. The thermoelectric generator according to claim 16, wherein a part of the exterior wall of the lamp is constituted using the heat absorption member.

24. The thermoelectric generator according to claim 16, wherein the heat absorption member has an internal space that communicates with an internal space of the lamp encompassed by the exterior wall.

25. The thermoelectric generator according to claim 24, wherein a plurality of fins are formed on an interior surface of the internal space of the heat absorption member.

26. The thermoelectric generator according to claim 24, wherein the heat absorption member has a heat radiation hole communicating with an exterior thereof.

27. The thermoelectric generator according to claim 16, wherein an exterior peripheral surface of the exterior wall of the lamp is covered with a heat insulating material except a part of the exterior peripheral surface of the exterior wall accompanied with the heat absorption member.

28. The thermoelectric generator according to claim 16 adapted to a projector, which is equipped with the lamp.

29. The thermoelectric generator according to claim 25, wherein the heat absorption member has a heat radiation hole communicating with an exterior thereof.

30. The thermoelectric generator according to claim 17, wherein an exterior peripheral surface of the exterior wall of the lamp is covered with a heat insulating material except a part of the exterior peripheral surface of the exterior wall accompanied with the heat absorption member.

31. The thermoelectric generator according to claim 17 adapted to a projector, which is equipped with the lamp.
